(19) United States
(12) Patent Application Publication
(10) Pub. No.: US 2024/0221684 A1
(43) Pub. Date: Jul. 4, 2024

(54) Display Device

(71) Applicant: LG Display Co., Ltd., Seoul (KR)

(72) Inventors: Dongho Choi, Paju-si (KR); Dahye Shim, Paju-si (KR); Sunghun Kim, Paju-si (KR); Yongmin Jeong, Paju-si (KR)

(21) Appl. No.: 18/520,495

(22) Filed: Nov. 27, 2023

(30) Foreign Application Priority Data
Dec. 30, 2022 (KR) 10-2022-0191148

(51) Int. Cl. G09G 3/3266; G09G 3/3275; H10K 59/121; H10K 59/131

(52) U.S. Cl. CPC G09G 3/3266; G09G 3/3275; H10K 59/1213; H10K 59/1216; H10K 59/131; G09G 2330/021

(57) ABSTRACT

A display device according to an embodiment of the present invention includes a display panel including a display area including a pixel and a scan driver connected to the pixel and a non-display area disposed around the display area and a first chip-on film attached to an end of the display panel, in which the non-display area includes a horizontal line area disposed between the first chip-on film and the display area and the horizontal line area includes a first horizontal line area and a second horizontal line area spaced apart from each other in a first direction.

### CROSS REFERENCE TO RELATED APPLICATIONS

The present application claims priority to Republic of Korea Patent Application No. 10-2022-0191148, filed Dec. 30, 2022, the entire contents of which is incorporated herein for all purposes by this reference.

### BACKGROUND

### Field

The present disclosure relates to a display device.

### Description of the Related Art

A display panel of a display device may include a display element for displaying an image, a drive element for driving the display element, and a line for transmitting various signals to the display element and the drive element. A display element may be defined differently according to the type of display panel. For example, when a display panel is an organic light-emitting display panel, the display element may be an organic light-emitting element that includes an anode, a light-emitting layer, and a cathode, without being limited thereto. As an example, the display element may also be a light emitting diode (LED) or a micro-LED etc.

The description provided in the background section should not be assumed to be prior art merely because it is mentioned in or associated with the background section. The background section may include information that describes one or more aspects of the subject technology.

### SUMMARY

The present specification intends to provide a display device including horizontal line areas separated from each other.

According to an embodiment to achieve the object described above, a display device includes: a display panel including a display area including a pixel and a scan driver connected to the pixel and a non-display area disposed around the display area; and a first chip-on film attached to the display panel, in which the non-display area includes a horizontal line area disposed between the first chip-on film and the display area on a plane, and the horizontal line area includes a first horizontal line area and a second horizontal line area spaced apart from each other in a first direction.

According to an embodiment, a display device includes a display panel including a display area and a non-display area, the display area including at least one pixel, and the non-display area including at least a first line area and a second line area spaced apart from the first line area in a first direction. The display device may further include a scan driver in the display area of the display panel, wherein the scan driver is configured to supply one or more scan signals to the at least one pixel, and wherein the scan driver includes at least a first stage circuit portion and a second stage circuit portion. The display device may further include a set of first lines disposed in the first line area, wherein the set of first lines are electrically connected to the first stage circuit portion to supply one or more scan control signals to the first stage circuit portion. The display device may further include a set of second lines disposed in the second line area, wherein the set of second lines are electrically connected to the second stage circuit portion to supply one or more scan control signals to the second stage circuit portion.

According to an embodiment, a display device includes a display panel including a display area and a non-display area, the display area including at least one pixel. The display device further includes a gate driver in the display area of the display panel, wherein the gate driver is configured to supply one or more gate signals to the at least one pixel. The display device further includes a set horizontal lines disposed in a horizontal line area in the non-display area, wherein the set of horizontal lines are electrically connected to the gate driver to supply one or more gate control signals to the gate driver. The display device further includes one or more first power lines disposed in the horizontal line area in the non-display area, wherein the one or more first power lines are electrically connected to the at least one pixel to supply one or more power voltages to the at least one pixel. The display device further includes one or more second power lines connected to the one or more first power lines, wherein the one or more second power lines intersect the set of horizontal lines.

The objects are not limited to those mentioned above, and other objects not mentioned will be clearly understood by those skilled in the art from the description below.

According to the embodiment, the display device may reduce the bezel area by including horizontal line areas separated from each other.

The effects according to the present specification are not limited to the examples described above, and other effects not mentioned will be clearly understood by those skilled in the art from the description below.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram schematically illustrating a display device according to an exemplary embodiment.

FIG. 2 is a cross-sectional view illustrating a stacked form of a display device according to an exemplary embodiment.

FIG. 3 is a view illustrating a configuration of a scan driver in a display device according to an exemplary embodiment.

FIG. 4 is a view illustrating a pixel circuit in a display device according to an exemplary embodiment.

FIGS. 5A to 5C are views illustrating the operations of a scan signal and a light emission control signal in a refresh period and a hold period in the pixel circuit illustrated in FIG. 4 according to an exemplary embodiment.

FIG. 6 is a plan layout of a display device according to an exemplary embodiment.

FIG. 7 is a detailed view of the plan layout of a display device according to FIG. 6 according to an exemplary embodiment.

FIG. 8 is a detailed plan layout of a first display area according to FIG. 7 according to an exemplary embodiment.

FIG. 9 is an enlarged plan view of the area A in FIG. 6 according to an exemplary embodiment.

FIG. 10 is a view illustrating a first horizontal line area and a second horizontal line area according to an exemplary embodiment.

FIG. 11 is a plan layout of a display device according to another exemplary embodiment.

FIG. 12 is a plan layout of a display device according to still another exemplary embodiment.

FIG. 13 is a plan layout of a display device according to still another exemplary embodiment.

FIG. 14 is a plan layout of a display device according to still another exemplary embodiment.

FIG. 15 is a plan layout of a display device according to still another exemplary embodiment.

FIG. 16 is a detailed plan layout of a first display area according to another exemplary embodiment.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages, features, and methods of achieving them will be made clear with reference to the embodiment described below and the accompanying drawings. However, the present specification is not limited to the following embodiment but will be implemented in various forms. The embodiments are provided to ensure full disclosure of the present invention and to fully inform those skilled in the art to which the present specification pertains of the scope of the disclosure. The present specification is only defined by the scope of the claims. Like reference numerals refer to the like components throughout the specification.

The shapes, sizes, ratios, angles, numbers, and the like, which are illustrated in the drawings to describe various example embodiments of the present disclosure are merely given by way of example. Therefore, the present disclosure is not limited to the illustrations in the drawings. In the following description where the detailed description of the relevant known function or configuration may unnecessarily obscure an important point of the present disclosure, a detailed description of such known function of configuration may be omitted. Any implementation described herein as an “example” is not necessarily to be construed as preferred or advantageous over other implementations.

In construing an element, the element is construed as including an error range or tolerance range although there is no explicit description of such an error or tolerance range.

When a component is referred to as being “connected to” or “coupled to” another component, the component is directly connected or coupled to the another component or other component may be interposed therebetween. In contrast, when a component is referred to as being “directly connected to” or “directly coupled to” another component, no other component is interposed therebetween. “And/or” includes every combination of one or more of the mentioned items.

In the description of the various embodiments of the present disclosure, where positional relationships are described, for example, when a position relation between two parts is described as, for example, “on,” “over,” “under,” and “next,” or the like, one or more other parts may be located between the two parts unless a more limiting term, such as “just” or “direct(ly)” is used. For example, where an element or layer is disposed “on” another element or layer, a third layer or element may be interposed therebetween.

The terms, such as “below,” “lower,” “above,” “upper” and the like, may be used herein to describe a relationship between elementitem(s) as illustrated in the drawings. It will be understood that the terms are spatially relative and based on the orientation depicted in the drawings.

The terms used herein are intended to describe embodiments and are not intended to limit the present specification. In the present specification, singular forms also include plural forms unless specifically stated otherwise. “Comprises” and/or “comprising” as used herein indicate that the presence of mentioned components, steps, operations, and/or elements do not exclude the presence or addition of other components, steps, operations, and/or elements.

Although first, second, “A,” “B,” “(a),” and “(b),” and the like are used to describe various components, the components are not limited by these terms. These terms are only used to distinguish one component from another.

The term “at least one” should be understood as including any and all combinations of one or more of the associated listed items. For example, the meaning of “at least one of a first item, a second item, and a third item” encompasses the combination of all three listed elements, combinations of any two of the three elements, as well as each individual element, the first element, the second element, and the third element.

Accordingly, it goes without saying that a first component referred to below may also be a second component within the technical idea. Unless otherwise stated, all terms (including technical and scientific terms) used herein may be used to have meanings that can be commonly understood by those skilled in the art to which the present specification pertains. In addition, terms defined in commonly used dictionaries are not to be construed ideally or excessively unless expressly defined specifically.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

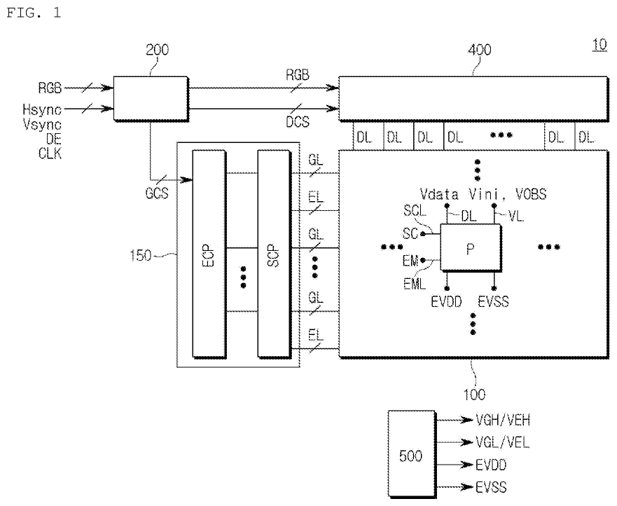

FIG. 1 is a block diagram schematically illustrating a display device according to an exemplary embodiment.

FIG. 1 shows that a display device 10 includes a display panel 100 including a plurality of pixels P, a controller 200, a scan driver 150 supplying a gate signal to each of the plurality of pixels P, a data driver 400 supplying a data signal to each of the plurality of pixels P, and a power supply unit 500 supplying power necessary for driving each of the plurality of pixels P, etc.

The display panel 100 includes a display area AA in which the pixels P are disposed and a non-display area NA that is disposed to be adjacent to or surround the display area AA. As an example, at least one of the scan driver 150 and the data driver 400 may be disposed in the non-display area NA, without being limited thereto. As an example, at least one of the scan driver 150 and the data driver 400 may be disposed to be connected to a bonding pad of the display panel 100 by a tape automated bonding TAB method or a chip-on-glass COG method. Alternatively, at least one of the scan driver 150 and the data driver 400 can be implemented by a chip-on-film COF method in which an element is mounted on a film connected to the display panel 100.

In the display panel 100, a plurality of scan lines SCL and a plurality of data lines DL cross each other, and each of the plurality of pixels P is connected to the scan line SCL and the data line DL. Specifically, one pixel P receives a gate signal from the scan driver 150 through the scan line SCL, a data signal from the data driver 400 through the data line DL, and high potential drive voltage EVDD and low potential drive voltage EVSS from the power supply unit 500.

Here, the scan line SCL supplies a scan signal SC and optionally a light emission control line EML supplies a light emission control signal EM, and the data line DL supplies data voltage Vdata. In addition, according to various embodiments, the scan line SCL may include a plurality of scan lines SCL supplying the scan signal SC and optionally a light emission control signal line EML supplying the light emission control signal EM. In addition, the plurality of pixels P may further include a power line VL to receive a bias voltage VOBS and/or an initialization voltage Var, Vini, etc.

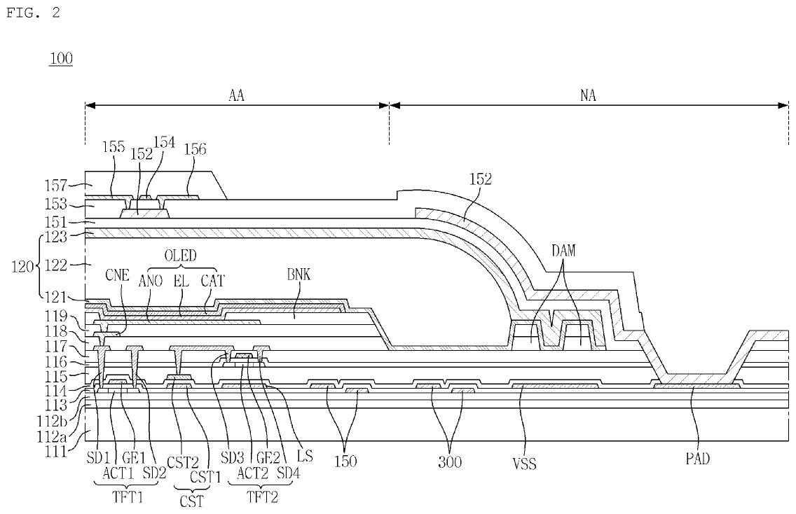

In addition, as illustrated in FIG. 2, each of the pixels P includes a light-emitting element OLED and a pixel circuit that controls the driving of the light-emitting element OLED. Here, the light-emitting element OLED includes an anode electrode ANO, a cathode electrode CAT, and a light-emitting layer EL between the anode electrode ANO and the cathode electrode CAT.

The pixel circuit includes a plurality of switching elements, a drive element, and a capacitor. Here, the switching element and the drive element may include a thin film transistor. The drive element controls the amount of current supplied to the light-emitting element OLED according to a data voltage to regulate the amount of light emission of the light-emitting element OLED in the pixel circuit. In addition, the plurality of switching elements receives a scan signal SC supplied through a plurality of scan lines SCL and optionally a light emission control signal EM supplied through the light emission control line EML and operates the pixel circuit.

The display panel 100 may be implemented as either a non-transmissive display panel or a transmissive display panel. A transmissive display panel may be applied to a transparent display device in which an image is displayed on the screen and the actual object in the background is visible. The display panel 100 may be made of a flexible display panel or a non-flexible display panel (e.g., rigid display panel). A flexible display panel may be implemented as an OLED panel using a plastic substrate or a thin glass substrate, without being limited thereto.

Each of the pixels P may be divided into a red pixel, a green pixel, and a blue pixel for color implementation. Each of the pixels P may further include a white pixel. Each of the pixels P includes a pixel circuit. But embodiments are not limited thereto. As an example, pixels of a combination of other colors, such as cyan, magenta and yellow, are also possible.

Touch sensors may be optionally disposed on the display panel 100. A touch input may be sensed using separate touch sensors or may be sensed through the pixels P. The touch sensors may be implemented either as an on-cell or add-on type sensor disposed on the screen of the display panel or as an in-cell type sensor embedded in the display panel 100.

The controller 200 processes the incoming image data RGB from external sources to match the size and resolution of the display panel 100 and supplies the processed data to the data driver 400. The controller 200 generates a gate control signal GCS and a data control signal DCS using synchronization signals from external sources, such as a dot clock signal CLK, a data enable signal DE, a horizontal synchronization signal Hsync, and a vertical synchronization signal Vsync and controls the scan driver 150 and the data driver 400 by supplying the generated gate control signal GCS and data control signal DCS to the scan driver 150 and the data driver 400 respectively.

The controller 200 may be configured in combination with various processors, for example, a microprocessor, a mobile processor, an application processor, and the like, depending on the device in which the controller is mounted.

The host system may be any one of a television TV system, a set-top box, a navigation system, a personal computer PC, a home theater system, a mobile system, a wearable device, and a vehicle system, etc.

The controller 200 may amplify the input frame frequency by a factor of i and control the operation timing of the display panel driver with the frame frequency of the amplified input frame frequency Xi Hz (i is a positive integer greater than 0). The input frame frequency is 60 Hz in the National Television Standard Committee (NTSC) method and 50 Hz in the phase-alternating line (PAL) method.

The controller 200 generates signals so that the pixel P can be driven at various refresh rates. As an example, the controller 200 generates driving-related signals so that the pixel P is driven in a variable refresh rate VRR mode or switchable between a first refresh rate and a second refresh rate. For example, the controller 200 may drive the pixel P at various refresh rates by simply changing the speed of the clock signal, generating a synchronization signal to create a horizontal blank or a vertical blank, or driving the scan driver 150 by a mask method.

The controller 200 generates the gate control signal GCS for controlling the operation timing of the scan driver 150 and the data control signal DCS for controlling the operation timing of the data driver 400 based on the timing signals Vsync, Hsync, DE received, for example, from the host system. The controller 200 synchronizes the scan driver 150 and the data driver 400 by controlling the operation timing of the display panel driver.

The voltage level of the gate control signal GCS output from the controller 200 may be converted into gate-on voltages VGL, VEL and gate-off voltages VGH, VEH through a level shifter (not shown) and supplied to the scan driver 150. The level shifter converts the low-level voltage of the gate control signal GCS into the gate-on voltage VGL and converts the high-level voltage of the gate control signal GCS into the gate-off voltage VGH, without being limited thereto. As an example, the level shifter may also convert the high-level voltage of the gate control signal GCS into the gate-on voltage VGL and converts the low-level voltage of the gate control signal GCS into the gate-off voltage VGH, depending the type of the transistor to be controlled. As an example, the gate control signal GCS includes a start pulse and a shift clock.

The scan driver 150 supplies the scan signal SC to the scan line SCL according to the gate control signal GCS supplied from the controller 200. As an example, the scan driver 150 may be disposed on one side or both sides of the display panel 100 by a gate-in-panel (GIP) method.

The scan driver 150 sequentially outputs gate signals to a plurality of scan lines SCL under the control of the controller 200. The scan driver 150 may sequentially supply the signals to the scan lines GL by shifting signals using a shift register.

The gate signal may include a scan signal SC and optionally a light emission control signal EM in an organic light-emitting display device. The scan signal SC includes a scan pulse swinging between the gate-on voltage VGL and the gate-off voltage VGH. The light emission control signal EM may include a light emission control signal pulse swinging between the gate-on voltage VEL and the gate-off voltage VEH.

The scan pulse is synchronized with the data voltage Vdata to select pixels P of a line to which data is to be written. The light emission control signal EM defines the light emission time of the pixels P.

The scan driver 150 may include at least one or more scan control drivers SCP and optionally a light emission control signal driver ECP. In one embodiment, the scan driver 150 is configured to receive one or more gate control signals that may include scan control signals and emission control signals. Each of the scan control driver SCP may be configured to receive one or more scan control signals and the light emission control signal driver ECP is configured to receive one or more emission control signals. The number of scan control signals may be different from a number of the emission control signals. In one embodiment, the scan driver 150 includes at least a second scan control driver SCP configured to receive one or more second scan control signals and is configured to generate at least one second scan signal, and a number of one or more first scan control signals to a first scan control driver SCP is different from a number of the one or more second scan control signals to the second scan control driver SCP. Moreover, signals of the one or more first scan control signals may be different from signals of the one or more second scan control signals.

The light emission control signal driver ECP outputs a light emission control signal pulse in response to a start pulse and a shift clock from the controller 200 and sequentially shifts light emission control signal pulses according to the shift clock.

At least one or more scan control drivers SCP outputs a scan pulse in response to the start pulse and shift clock from the controller 200 and shifts the scan pulse according to the shift clock timing.

The data driver 400 converts the image data RGB into data voltage Vdata according to the date control signal DCS supplied from the controller 200 and supplies the converted data voltage Vdata to the pixel P through the data line DL.

The data driver 400 is illustrated as being disposed in one block on one side of the display panel 100 in FIG. 1, but the number and location of the data driver 400 are not limited thereto.

That is, the data driver 400 may include a plurality of integrated circuits IC, which may be disposed on one or more sides of the display panel 100 as separate multiple units. In one embodiment, the data driver 400 may be connected to the display panel 100 to supply the set of gate control signals to horizontal lines of the horizontal line areas described herein. The data driver 400 may be implemented as a chip-on-film (COF) including a film and the data driver 400 may be integrated circuits on the film.

The power supply unit 500 generates the DC power necessary for driving the pixel array of the display panel 100 and the display panel driver, for example, by using a DC-DC converter. The DC-DC converter may include a charge pump, a regulator, a buck converter, a boost converter, and the like. The power supply unit 500 may receive a DC input voltage applied, for example, from a host system (not shown) and generate DC voltages such as gate-on voltages VGL, VEL, gate-off voltages VGH, VEH, high potential drive voltages EVDD, and low potential drive voltages EVSS. The gate-on voltages VGL, VEL and gate-off voltages VGH, VEH are supplied to a level shifter (not shown) and the scan driver 150. The high potential drive voltage EVDD and the low potential drive voltage EVSS are commonly supplied to the pixels P.

FIG. 2 is a cross-sectional view illustrating a stacked form of a display device according to an exemplary embodiment.

The cross-sectional view in FIG. 2 includes two thin film transistors TFT1, TFT2 and one capacitor CST. As an example, the two thin film transistors TFT1, TFT2 include a polycrystalline thin film transistor TFT1 including a polycrystalline semiconductor material, which is either a switching thin film transistor or a drive transistor, and an oxide thin film transistor TFT2 including an oxide semiconductor material, without being limited thereto. As an example, the two thin film transistors TFT1, TFT2 may also include two polycrystalline thin film transistors or two oxide thin film transistors, or thin film transistors including semiconductor materials other than the polycrystalline semiconductor material and the oxide semiconductor material. In this case, the thin film transistor including a polycrystalline semiconductor material is referred to as a polycrystalline thin film transistor, and the thin film transistor including an oxide semiconductor material is referred to as an oxide thin film transistor.

The polycrystalline thin film transistor TFT1 illustrated in FIG. 2 is an emission-switching thin film transistor connected to a light-emitting element OLED, and the oxide thin film transistor TFT2 is one of the switching thin film transistors connected to the capacitor CST, without being limited thereto.

One pixel P includes a light-emitting element OLED and a pixel drive circuit that supplies a drive current to the light-emitting element OLED. The pixel drive circuit is disposed on a substrate 111, and the light-emitting element OLED is disposed on the pixel drive circuit. A sealing layer 120 is disposed on the light-emitting element OLED. The sealing layer 120 protects the light-emitting element OLED.

A pixel drive circuit may refer to one pixel P array portion, which includes a drive thin film transistor, a switching thin film transistor, and a capacitor, etc. Also, the light-emitting element OLED may refer to an array portion for emitting light, which includes an anode electrode, a cathode electrode, and a light-emitting layer disposed therebetween.

In one embodiment, the drive thin film transistor and/or at least one switching thin film transistor use an oxide semiconductor as an active layer. A thin film transistor using an oxide semiconductor material as an active layer is highly effective in cutting off leakage current and is relatively inexpensive to manufacture compared to a thin film transistor using a polycrystalline semiconductor material as an active layer. Therefore, in order to reduce power consumption and manufacturing cost, a pixel drive circuit according to the embodiment includes a drive thin film transistor and/or at least one switching thin film transistor using an oxide semiconductor material, without being limited thereto.

All the thin film transistors constituting the pixel drive circuit may be implemented using an oxide semiconductor material, or only some of the thin film transistors may be implemented using an oxide semiconductor material.

However, since it is difficult to secure the reliability of a thin film transistor using an oxide semiconductor material and a thin film transistor using a polycrystalline semiconductor material has a high operating speed and excellent reliability, as an example, both the switching thin film transistor using an oxide semiconductor material and the switching thin film transistor using a polycrystalline semiconductor material may be included in one embodiment.

The substrate 111 may be implemented as a single layer or a multi-layer in which organic layers and inorganic layers are alternately stacked. For example, organic layers such as polyimide, polyethylene terephthalate (PET), and polyethylene naphthalate (PEN), etc. and inorganic layers such as silicon oxide SiO₂, a silicon nitride layer SiNx, and a silicon oxynitride layer SiOxNy, etc. may be alternately stacked on the substrate 111, without being limited thereto.

A lower buffer layer 112a is formed on the substrate 111. The lower buffer layer 112a is for blocking moisture or the like that may enter from the outside. As an example, silicon oxide SiO₂, silicon nitride layer SiNx, silicon oxynitride layer SiOxNy or the like may be stacked in multiple layers in the lower buffer layer 112a. An auxiliary buffer layer 112b may be further disposed on the lower buffer layer 112a to protect the element from moisture.

A polycrystalline thin film transistor TFT1 is formed on the substrate 111. The polycrystalline thin film transistor TFT1 may use a polycrystalline semiconductor as an active layer. The polycrystalline thin film transistor TFT1 includes a first active layer ACT1 including a channel for electrons or holes to move through, a first gate electrode GE 1, a first source electrode SD1, and a first drain electrode SD2.

The first active layer ACT1 includes a first channel area and a first source area disposed on one side and a first drain area disposed on the other side with the first channel area interposed therebetween.

The first source area and the first drain area are areas in which group 5 or 3 impurity ions such as phosphorus P or boron B, for example, are doped at a predetermined concentration to form a conductor, without being limited thereto. The first channel area maintains the intrinsic state of the polycrystalline semiconductor material, and provides a pathway for electrons or holes to move through.

On the other hand, the polycrystalline thin film transistor TFT1 includes a first gate electrode GE1 overlapping the first channel area in the first active layer ACT1. A first gate insulating layer 113 is disposed between the first gate electrode GE1 and the first active layer ACT1. A single layer or stacked multiple layers of an inorganic layer of silicon oxide (SiO₂), silicon nitride (SiNx), or the like may be used in the first gate insulating layer 113. In one embodiment, the data lines DL may be formed in a same layer as the first gate electrode GE1.

In an embodiment, the polycrystalline thin film transistor TFT1 may have a top gate structure with the first gate electrode GE1 positioned over the first active layer ACT1. Accordingly, the first electrode CST1 included in the capacitor CST and an optional light-blocking layer LS included in the oxide thin film transistor TFT1 may be formed of the same material in the same layer as the first gate electrode GE1. A mask process may be reduced by forming the first gate electrode GE1, the first electrode CST1, and the light-blocking layer LS through one mask process.

The first gate electrode GE1 is made of a metal material. For example, the first gate electrode GE1 may be a single layer or a multi-layer made of any one or any alloy of molybdenum (Mo), aluminum (Al), chromium (Cr), gold (Au), titanium (Ti), nickel (Ni), neodymium (Nd), and copper (Cu), etc., but is not limited thereto.

A first interlayer insulating layer 114 is disposed on the first gate electrode GE1. The first interlayer insulating layer 114 may be implemented with silicon oxide SiO₂, silicon nitride SiNx, or the like.

The display panel 100 may further include an upper buffer layer 115, a second gate insulating layer 116, and a second interlayer insulating layer 117 sequentially disposed on the first interlayer insulating layer 114, and the polycrystalline thin film transistor TFT1 includes the first source electrode SD1 and the first drain electrode SD2 respectively connected to the first source area and the first drain area and formed on the second interlayer insulating layer 117, without being limited thereto.

The first source electrode SD1 and the first drain electrode SD2 may be a single layer or a multi-layer made of any one or any alloy of molybdenum (Mo), aluminum (Al), chromium (Cr), gold (Au), titanium (Ti), nickel (Ni), neodymium (Nd), and copper (Cu), etc., but is not limited thereto.

The upper buffer layer 115 spaces apart the second active layer ACT2 of the oxide thin film transistor TFT2 implemented with an oxide semiconductor material from the first active layer ACT1 implemented with a polycrystalline semiconductor material and provides a basis for forming the second active layer ACT2.

The second gate insulating layer 116 covers the second active layer ACT2 of the oxide thin film transistor TFT2. The second gate insulating layer 116 is formed on the second active layer ACT2 implemented with an oxide semiconductor material so that the second gate insulating layer 116 is implemented as an inorganic film. For example, the second gate insulating layer 116 may be made of silicon oxide (SiO₂) or silicon nitride (SiNx), etc.

The second gate electrode GE2 includes a metallic material. For example, the second gate electrode GE2 may be a single layer or a multi-layer made of any one or any alloy of molybdenum (Mo), aluminum (Al), chromium (Cr), gold (Au), titanium (Ti), nickel (Ni), neodymium (Nd), and copper (Cu), but is not limited thereto.

On the other hand, the oxide thin film transistor TFT2 is formed on the upper buffer layer 115 and includes the second active layer ACT2 implemented with an oxide semiconductor material, a second gate electrode GE2 disposed on the second gate insulating layer 116, and a second source electrode SD3 and a second drain electrode SD4 disposed on the second interlayer insulating layer 117.

The second active layer ACT2 is implemented with an oxide semiconductor material and includes a second channel area in which impurities are not doped, and a second source area and a second drain area in which impurities are doped to form a conductor.

The oxide thin film transistor TFT2 further optionally includes a light-blocking layer LS positioned under the upper buffer layer 115 and overlapping the second active layer ACT2. The light-blocking layer LS may secure the reliability of the oxide thin film transistor TFT2 by blocking the light incident on the second active layer ACT2. The light-blocking layer LS may be formed of the same material as the first gate electrode GE1 and/or may be formed on the upper surface of the first gate insulating layer 113. As an example, the light-blocking layer LS may be electrically connected to the second gate electrode GE2 to form a dual gate.

The number of mask processes may be reduced by simultaneously forming the second source electrode SD3 and the second drain electrode SD4 along with the first source electrode SD1 and the first drain electrode SD2 with the same material on the second interlayer insulating layer 117.

On the other hand, the capacitor CST may be implemented by disposing the second electrode CST2 to overlap the first electrode CST1 on the first interlayer insulating layer 114. For example, the second electrode CST2 may be a single layer or a multi-layer made of any one or any alloy of molybdenum (Mo), aluminum (Al), chromium (Cr), gold (Au), titanium (Ti), nickel (Ni), neodymium (Nd), and copper (Cu), but is not limited thereto. In one embodiment, the data lines DL are formed in a same layer as the second capacitor electrode CST2.

The capacitor CST stores the data voltage applied through the data line DL for a certain time and provides the stored data voltage to the light-emitting element OLED. The capacitor CST includes two electrodes corresponding to each other and a dielectric interposed therebetween. As an example, the first interlayer insulating layer 114 is positioned between the first electrode CST1 and the second electrode CST2.

The first electrode CST1 or the second electrode CST2 of the capacitor CST may be electrically connected to the second source electrode SD3 or the second drain electrode SD4 of the oxide thin film transistor TFT2. However, the connection relationship of the capacitor CST may change according to the pixel drive circuit without being limited thereto.

On the other hand, a first planarization layer 118 and/or a second planarization layer 119 may be (e.g., sequentially) disposed on the pixel drive circuit to planarize the top of the pixel drive circuit. The first planarization layer 118 and the second planarization layer 119 may be organic films such as polyimide or acrylic resin, without being limited thereto.

A light-emitting element OLED is formed on the second planarization layer 119.

The light-emitting element OLED includes an anode electrode ANO, a cathode electrode CAT, and a light-emitting layer EL disposed between the anode electrode ANO and the cathode electrode CAT. The anode electrode ANO is disposed as a separate electrode for each sub-pixel, for example, when implementing a pixel drive circuit that shares a low potential voltage connected to the cathode electrode CAT. The cathode electrode CAT may be disposed as a separate electrode for each sub-pixel, for example, when implementing a pixel drive circuit that shares a high potential voltage.

The light-emitting element OLED is electrically connected to the drive element through an optional intermediate electrode CNE disposed on the first planarization layer 118. Specifically, the anode electrode ANO of the light-emitting element OLED and the first source electrode SD1 of the polycrystalline thin film transistor TFT1 constituting the pixel drive circuit are connected to each other by the intermediate electrode CNE. In another instance the intermediate electrode CNE may be connected to the first drain electrode SD2.

The anode electrode ANO is connected to the exposed intermediate electrode CNE through a contact hole passing through the second planarization layer 119. In addition, the intermediate electrode CNE is connected to the exposed first source electrode SD1 through a contact hole passing through the first planarization layer 118.

The intermediate electrode CNE serves as a medium connecting the first source electrode SD1 and the anode electrode ANO. The intermediate electrode CNE may be formed of a conductive material such as copper (Cu), silver (Ag), molybdenum (Mo), or titanium (Ti), etc.

The anode electrode ANO may have a single layer structure or a multilayer structure. As an example, the anode electrode ANO may have a multilayer structure including a transparent conductive film and an opaque conductive layer having high reflective efficiency. The transparent conductive film may be made of a material having a relatively large work function value such as indium-tin-oxide (ITO) or indium-zinc-oxide (IZO), and the opaque conductive film may be structured in a single layer or multilayer including aluminum (Al), silver (Ag), copper (Cu), lead (Pb), Molybdenum (Mo), titanium (Ti), or an alloy thereof, without being limited thereto. For example, the anode electrode ANO may have a structure with a transparent conductive film, an opaque conductive film, and a transparent conductive film sequentially stacked, or a transparent conductive film and an opaque conductive film sequentially stacked, without being limited thereto.

As an example, the light-emitting layer EL may be formed by an organic light-emitting layer. As an example, the light-emitting layer EL is formed by stacking a hole-related layer, the organic light-emitting layer, and an electron-related layer on the anode electrode ANO in order or in reversed order, without being limited thereto.

The bank layer BNK may be a pixel-defining film that exposes the anode electrode ANO of each pixel P. The bank layer BNK may be formed of an opaque material (e.g., black) to prevent or reduce light interference between adjacent pixels P. In this case, the bank layer BNK includes a light-blocking material made of at least one of color pigment, organic black, and carbon, etc. A spacer may be optionally further disposed on the bank layer BNK.

The cathode electrode CAT is formed on the light-emitting layer EL. As an example, the cathode electrode CAT may be formed on the upper and side surfaces of the light-emitting layer EL, across from the anode electrode ANO with the light-emitting layer EL interposed therebetween. As an example, the cathode electrode CAT may be integrally formed over the entire display area AA. The cathode electrode CAT may be made of a conductive film. As an example, the cathode electrode CAT may be made of a transparent conductive film such as indium-tin-oxide (ITO) or indium-zinc-oxide (IZO) when applied to a front-emitting organic light-emitting display device.

A sealing layer 120 suppressing or reducing moisture permeation may be further disposed on the cathode electrode CAT.

The sealing layer 120 may block or reduce the permeation of external moisture or oxygen into the light-emitting element EL, which is vulnerable to moisture or oxygen. To this end, the sealing layer 120 may include at least one inorganic sealing layer and at least one organic sealing layer but is not limited thereto. In the present invention, the structure of the sealing layer 120 with the first sealing layer 121, the second sealing layer 122, and the third sealing layer 123 sequentially stacked will be described as an example.

A first sealing layer 121 is formed on the substrate 111 on which the cathode electrode CAT is formed. A third sealing layer 123 is formed on the substrate 111 on which a second sealing layer 122 is formed, and in an example, along with the first sealing layer 121, may be formed to surround the top, bottom and side surfaces of the second sealing layer 122. The first sealing layer 121 and the third sealing layer 123 may minimize or prevent the permeation of external moisture or oxygen into the light-emitting element EL. The first sealing layer 121 and the third sealing layer 123 are made of an inorganic insulating material. As an example, the first sealing layer 121 and the third sealing layer 123 may be made of an inorganic insulating material that can be deposited at a low temperature, such as silicon nitride (SiNx), silicon oxide (SiOx), silicon oxynitride (SiON), or aluminum oxide (Al₂O₃), etc. Since the first sealing layer 121 and the third sealing layer 123 are deposited in a low-temperature atmosphere, damage to the light-emitting element EL vulnerable to a high-temperature atmosphere can be reduced or prevented during the deposition process of the first sealing layer 121 and the third sealing layer 123.

The second sealing layer 122 serves as a buffer. As an example, the second sealing layer 122 may serve as a buffer to relieve stress between the respective layers caused, for example, by bending of the display device 10 and can smooth out the layers. The second sealing layer 122 may be formed of non-light-emitting organic insulating materials such as acrylic resin, epoxy resin, phenolic resin, polyamide resin, polyimide resin, polyethylene, and silicon oxycarbide (SiOC) or photosensitive organic insulating materials such as photoacrylic on the substrate 111 on which first sealing layer 121 is formed, and is not limited thereto. When the second sealing layer 122 is formed by an inkjet method, a dam DAM may be disposed to reduce or prevent the second sealing layer 122 in a liquid state from diffusing to the edge of the substrate 111. The dam DAM may be disposed closer to the edge of the substrate 111 than the second sealing layer 122. The second sealing layer 122 may be mitigated or prevented by such a dam DAM from diffusing into the edge of the substrate 111, particularly, the pad area where the conductive pads to be disposed at the outermost edge of the substrate 111 are disposed.

The dam DAM is designed to reduce or prevent the diffusion of the second sealing layer 122, but when the second sealing layer 122 is formed to be taller than dam DAM during the process, the second sealing layer, which is an organic layer, may be exposed to the outside and thus make it easy for moisture or the like to permeate the inside of the light-emitting element. Therefore, to prevent this, as an example, ten or more dams DAM may be formed in duplicates.

The dam DAM may be disposed on the second interlayer insulating layer 117 of the non-display area NA.

In addition, the dam DAM may be formed simultaneously with the first planarization layer 118 and/or the second planarization layer 119, without being limited thereto. As an example, the lower layer of the dam DAM may be simultaneously formed when the first planarization layer 118 is formed, and the upper layer of the dam DAM may be simultaneously formed when the second planarization layer 119 is formed.

Accordingly, the dam DAM may be made of the same material as the first planarization layer 118 and the second planarization layer 119 but is not limited thereto.

The dam DAM may be formed to overlap the low potential drive power line VSS, without being limited thereto. For example, in the non-display area NA, the low potential driving power line VSS may be formed in the lower layer of the area where the dam DAM is positioned.

The low potential drive power line VSS may be positioned outside of the scan driver 150. In addition, as an example, the low potential drive power line VSS may be connected to the cathode electrode CAT to apply a common voltage.

On the other hand, as illustrated in FIG. 2, as an example, the scan driver 150 may be disposed in the display area AA.

The low potential drive power line VSS is disposed outside of the scan driver 150. The low potential drive power line VSS is disposed outside of the scan driver 150 and at least partially surrounds the display area AA. For example, the low potential drive power line VSS may be made of the same material as the first gate electrode GE1, but is not limited to it, and may be made of the same material as the second electrode CST2 or the first source and drain electrodes SD1, SD2, but is not limited thereto.

In addition, the low potential drive power line VSS may be electrically connected to the cathode electrode CAT. The low potential drive power line VSS may supply low potential drive voltage EVSS to the plurality of pixels P of the display area AA.

A touch layer may be optionally disposed on the sealing layer 120. A touch buffer film 151 may be positioned between a touch sensor, which for example includes touch electrode connection lines 152, 154 and touch electrodes 155, 156, and the cathode electrode CAT of the light-emitting element EL.

The touch buffer film 151 may reduce or block the permeation of a chemical solution used in the fabrication process of the touch sensor disposed on the touch buffer film 151 or moisture from the outside into the light-emitting layer EL containing an organic matter. Accordingly, the touch buffer film 151 may reduce or prevent damage to the light-emitting layer EL vulnerable to chemical solutions or moisture.

As an example, the touch buffer layer 151 is formed of an organic insulating material that can be formed at a certain temperature (e.g., 100 degrees or less) and/or has a low dielectric constant of 1 to 3 to reduce or prevent damage to the light-emitting layer EL containing organic matter vulnerable to a high temperature. For example, the touch buffer film 151 may be formed of acryl-based, epoxy-based, or siloxane-based material. The touch buffer film 151 which is formed of an organic insulating material and/or has a planarization capacity may reduce or prevent damage to the sealing layer 120 and the cracking of the touch sensor formed on the touch buffer film 151 caused, for example, by bending of the organic light-emitting display device.

According to the mutual-capacitance-based touch sensor structure, the touch electrodes 155, 156 may be disposed on the touch buffer layer 151, and the touch electrodes 155, 156 may be disposed to cross each other, without being limited thereto. As an example, a self-capacitance-based touch sensor structure may be applied.

The touch electrode connection lines 152, 154 may electrically connect the touch electrodes 155, 156 to each other. The touch electrode connection lines 152, 154 and the touch electrodes 155, 156 may be positioned on different layers with the touch insulating layer 153 interposed therebetween.

As an example, the touch electrode connection lines 152, 154 may be disposed to at least partially overlap the bank layer 165 to reduce or prevent the aperture ratio from lowering. As another example, the touch electrode connection lines 152, 154 may be formed of a transparent conductive material such as indium-tin-oxide (ITO) or indium-zinc-oxide (IZO), while overlapping or not overlapping the bank layer 165.

On the other hand, in the touch electrodes 155, 156, a part of the touch electrode connection line 152 may pass through the top and side surfaces of the sealing layer 120 and the top and side surfaces of the dam DAM and be electrically connected to a touch drive circuit (not shown), for example, via a touch pad PAD.

At least some of the touch electrode connection lines 152 may receive a touch drive signal from the touch drive circuit and transmit the signal to the touch electrodes 155, 156 and at least some of the touch electrode connection lines 152 may transmit a touch sensing signal from the touch electrodes 155, 156 to the touch drive circuit, without being limited thereto.

A touch protection film 157 may be disposed on the touch electrodes 155, 156. In the diagram, the touch protection film 157 is shown to be disposed only on the touch electrodes 155, 156 but is not limited thereto. As an example, the touch protection film 157 may extend before or beyond the dam DAM to be disposed on the touch electrode connection line 152.

In addition, a color filter (not shown) may be optionally further disposed on the sealing layer 120, and the color filter may be positioned either on the touch layer or between the sealing layer 120 and the touch layer, without being limited thereto.

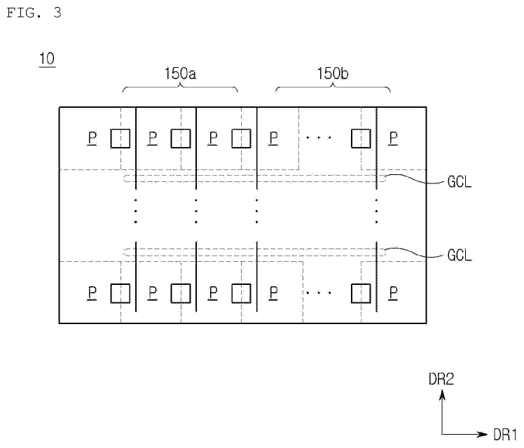

FIG. 3 is a view illustrating a configuration of a scan driver in a display device according to an embodiment.

The scan driver 150 according to an embodiment may be implemented (or embedded) in the display area AA of the substrate 111. As an example, the scan driver 150 may generate gate signals including a scan signal or a light emission control signal based on a gate control signal or a an emission control signal supplied through a pad portion and gate control lines GCL and sequentially supply the scan signal to a plurality of scan lines SCL or light emission control lines EML.

The gate control lines GCL may include a start signal line, a plurality of shift clock lines, at least one gate drive voltage line, and at least one gate common voltage line. The gate control lines GCL may be disposed in the display area AA of the substrate 111 to extend in a second direction DR2 and have a predetermined interval in a first direction DR1. For example, at least one pixel P in the first direction DR1 may be disposed between the adjacent gate control lines GCL.

As illustrated in FIG. 3, the scan driver 150 according to an embodiment may be implemented as a shift register including a first stage circuit portion 150a and a second stage circuit portion 150b. The first stage circuit portion 150a and the second stage circuit portion 150b may be spaced apart from each other in the first direction DR1. The first stage circuit portion 150a and the second stage circuit portion 150b may be separately disposed in the first direction DR1 and each of the first stage circuit portion 150a and the second stage circuit portion 150b may be dependently connected to each other in the second direction DR2. The first stage circuit portion 150a and the second stage circuit portion 150b may respectively generate scan signals in a predetermined order in response to the gate control signal supplied through the pad portion and the gate control lines GCL and supply the generated scan signals to the scan line SCL. Each of the first stage circuit portion 150a and the second stage circuit portion 150b will be described in detail later.

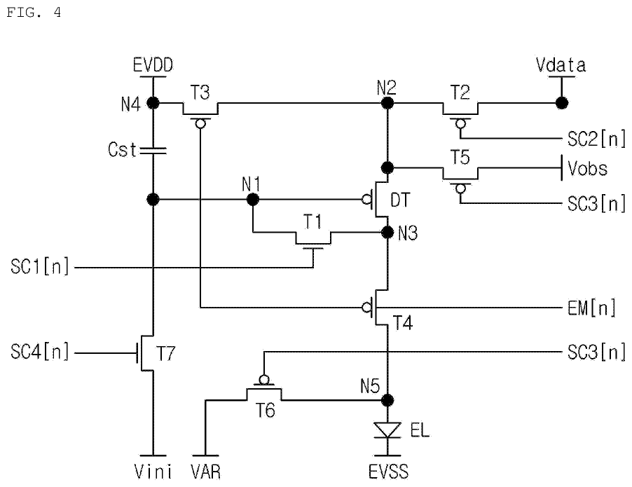

FIG. 4 is a view illustrating a pixel circuit in a display device according to an exemplary embodiment.

FIG. 4 illustrates an exemplary pixel circuit for illustrative purposes only, and there is no limit as long as the light emission of the light-emitting element EL may be controlled by the application of the light emission signal EM(n). For example, the pixel circuit may include an additional scan signal and a switching thin film transistor connected thereto and/or a switching thin film transistor to which an additional initialization voltage is applied, and various connection relationships of the switching elements and connection positions of the capacitor may be arranged. A display device having the pixel circuit structure of FIG. 4 will be described below for convenience of description.

FIG. 4 shows that each of the plurality of pixels P may include a pixel circuit with a drive transistor DT and a light-emitting element EL connected to the pixel circuit.

The pixel circuit may drive the light-emitting element EL by controlling a drive current flowing to the light-emitting element EL. The pixel circuit may include a drive transistor DT, first to seventh transistors T1 to T7, and a capacitor Cst. Each of the transistors DT, T1 to T7 may include a first electrode, a second electrode, and a gate electrode. One of the first electrode and the second electrode may be a source electrode, and the other of the first electrode and the second electrode may be a drain electrode.

Each of the transistors DT, T1 to T7 may be a P-type thin film transistor or an N-type thin film transistor. In the embodiment of FIG. 4, the first transistor T1 and the seventh transistor T7 are N-type thin film transistors, while the rest transistors DT, T2 to T6 are P-type thin film transistors. However, the transistors are not limited thereto, and according to the embodiment, all or some of the transistors DT, T1 to T7 may be P-type thin film transistors or N-type thin film transistors. In addition, the N-type thin film transistor may be an oxide thin film transistor, and the P-type thin film transistor may be a polycrystalline silicon thin film transistor, without being limited thereto. According to the embodiment, all or some of the transistors DT, T1 to T7 may be an oxide thin film transistor or a polycrystalline silicon thin film transistor.

Hereinafter, for illustrative purposes, the first transistor T1 and the seventh transistor T7 are N-type thin film transistors, and the rest transistors DT, T2 to T6 are P-type thin film transistors. Accordingly, the first transistor T1 and the seventh transistor T7 are turned on by applying a high voltage, and the rest transistors DT, T2 to T6 are turned on by applying a low voltage.

According to an embodiment, the first transistor T1 constituting a pixel circuit may function as a compensation transistor, the second transistor T2 may function as a data supply transistor, the third and fourth transistors T3, T4 may function as light emission control transistors, the fifth transistor T5 may function as a bias transistor, and the sixth and seventh transistors T6, T7 may function as initialization transistors.

The light-emitting element EL may include an anode electrode (or pixel electrode) and a cathode electrode. The anode electrode of the light-emitting element EL may be connected to a fifth node N5 and the cathode electrode may be connected to the low potential drive voltage EVSS, without being limited thereto.

The drive transistor DT may include a first electrode connected to a second node N2, a second electrode connected to a third node N3, and a gate electrode connected to a first node N1. The drive transistor DT may provide a drive current Id to the light-emitting element EL based on the voltage of the first node N1 (or data voltage stored in the capacitor Cst to be described below).

The first transistor T1 may include a first electrode connected to the first node N1, a second electrode connected to the third node N3, and a gate electrode receiving a first scan signal SC1(n). The first transistor T1 is turned on in response to the first scan signal SC1(n), and the data voltage Vdata may sample the threshold voltage Vth of the drive transistor DT by diode-connecting the drive transistor DT between the first node N1 and the third node N3. The first transistor T1 may be a compensation transistor.

The capacitor Cst may be connected or formed between the first node N1 and the fourth node N4. The capacitor Cst may store or maintain the provided high potential drive voltage EVDD.

The second transistor T2 may include a first electrode connected to the data line DL (or receiving the data voltage Vdata), a second electrode connected to the second node N2, and a gate electrode receiving a second scan signal SC2 (n). The second transistor T2 may be turned on in response to the second scan signal SC2(n) and transmit the data voltage Vdata to the second node N2. The second transistor T2 may be a data supply transistor.

The third transistor T3 and the fourth transistor T4 (or the first and second light emission control transistors) may be connected between the high potential drive voltage EVDD and the light-emitting element EL and form a current traveling path through which the drive current Id generated by the drive transistor DT travels.

The third transistor T3 may include a first electrode connected to the fourth node N4 to receive the high potential drive voltage EVDD, a second electrode connected to the second node N2, and a gate electrode receiving a light emission control signal EM(n).

The fourth transistor T4 may include a first electrode connected to the third node N3, a second electrode connected to the fifth node N5 (or anode electrode of the light-emitting element EL), and a gate electrode receiving the light emission control signal EM(n).

The third and fourth transistors T3, T4 may be turned on in response to the light emission control signal EM(n), and in this case, the drive current Id may be provided to the light-emitting element EL and the light-emitting element EL may emit light with luminance corresponding to the drive current Id.

The fifth transistor T5 may include a first electrode receiving a bias voltage Vobs, a second electrode connected to the second node N2, and a gate electrode receiving a third scan signal SC3(n). The fifth transistor T5 may be a bias transistor.

The sixth transistor T6 may include a first electrode receiving a first initialization voltage Var, a second electrode connected to the fifth node N5, and a gate electrode receiving a third scan signal SC3(n).

The sixth transistor T6 may be turned on in response to the third scan signal SC3(n) before the light-emitting element EL emits light (or after the light-emitting element EL emits light) and initialize the anode electrode (or pixel electrode) of the light-emitting element EL using the first initialization voltage VAR. The light-emitting element EL may have a parasitic capacitor formed between the anode electrode and cathode electrode. The capacitor may be charged while the light-emitting element EL emits light so that the anode electrode of the light-emitting element EL may have a certain voltage. Accordingly, the amount of charge accumulated in the light-emitting element EL may be reset by applying the first initialization voltage VAR to the anode electrode of the light-emitting element EL through the sixth transistor T6.

In the present specification, the gate electrodes of the fifth and sixth transistors T5, T6 are configured to receive the third scan signal SC3(n) jointly but are not limited thereto. The gate electrodes of the fifth and sixth transistors T5, T6 may be configured to receive separate scan signals and be controlled independently.

The seventh transistor T7 may include a first electrode receiving a second initialization voltage Vini, a second electrode connected to the first node N1, and a gate electrode receiving a fourth scan signal SC4(n).

The seventh transistor T7 may be turned on in response to the fourth scan signal SC4(n) and initialize the gate electrode of the drive transistor DT using the second initialization voltage Vini. The gate electrode of the drive transistor DT may retain unwanted charge due to the high potential drive voltage EVDD stored in the capacitor Cst. Accordingly, the amount of residual charge may be reset by applying the second initialization voltage Vini to the gate electrode of the drive transistor DT through the seventh transistor T7.

Although four scan signals and one light emission control signal for one pixel are described and illustrated in FIG. 4, the number of the scan signals and the light emission control signal for one pixel are not limited thereto. As an example, one pixel may receive at least one scan signals, and may receive one or more light emission control signals or doesn't receive any light emission control signal. In this case, the number of scan lines connected to one pixel may be adjusted correspondingly.

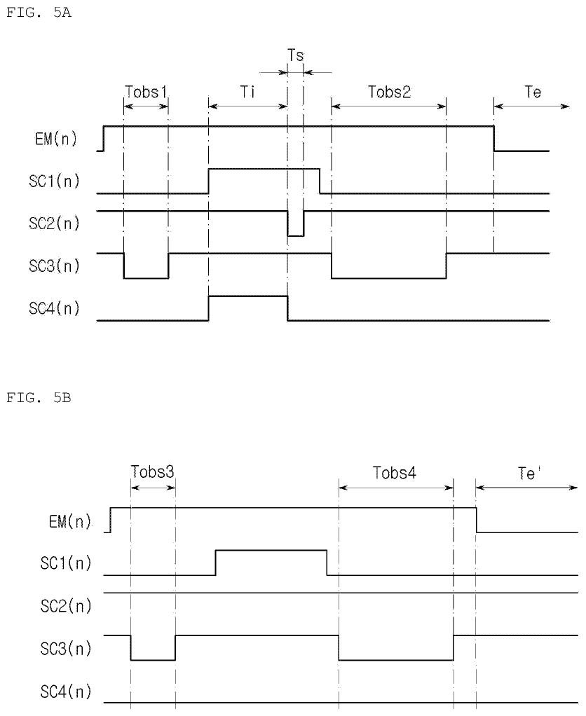

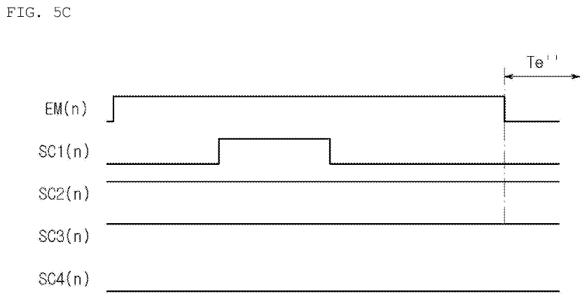

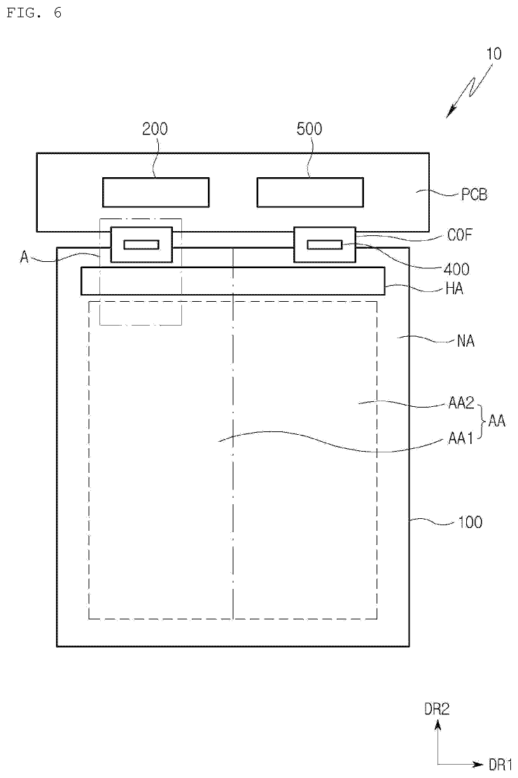

FIGS. 5A to 5C are views illustrating the operations of a scan signal and a light emission control signal in a refresh period and a hold period in the pixel circuit illustrated in FIG. 4.

As an example, the display device in the embodiment may operate in the variable refresh rate VRR mode. In the VRR mode, while driven at a constant frequency, the pixels may be operated by increasing the refresh rate at which the data voltage Vdata is updated, for example, when high speed drive is required or by decreasing the refresh rate, for example, when low power consumption or low-speed drive is required.

Each of the plurality of pixels P may be driven through a combination of a refresh frame and a hold frame within one second. In the present specification, one set is defined as a combination of a refresh period during which the data voltage Vdata is updated and a hold period during which the data voltage Vdata is not updated, repeating itself in one second. And one set period becomes a cycle in which the combination of the refresh period and the hold period repeat itself once.

The pixel is driven in a fresh period only when the refresh rate is set to 120 Hz. That is, the number of refresh periods may be 120 during one second of driving. The duration of one refresh period is 1/120=8.33 ms, and one set period is also 8.33 ms.

When the refresh rate is set to 60 Hz, the refresh period and the hold period may be alternately driven. As an example, the refresh period may alternate with the hold period 60 times during one second of driving. One refresh period and one hold period are 0.5/60=8.33 ms each, and one set period is 16.66 ms.

When the refresh rate is set to 1 Hz, one frame may be driven during one refresh period and 119 hold periods, for example, after the one refresh period. In addition, when the refresh rate is set to 1 Hz, one frame may be driven during a plurality of refresh periods and a plurality of hold periods. At this time, one refresh period and one hold period are 1/120=8.33 ms respectively, and one set period is 1 s.

New data voltage Vdata is charged and applied to the drive transistor DT in the refresh period, while the data voltage Vdata of the previous frame is maintained and used in the hold period. On the other hand, the hold period is also referred to as a skip period in the sense that a process of applying a new data voltage Vdata to the drive transistor DT is omitted.

Each of the plurality of pixels P may be charged in the pixel circuit or the residual voltage may be reset during the refresh period. Specifically, each of the plurality of pixels P may remove the influence of the data voltage Vdata and high potential drive voltage EVDD stored in the previous frame during the refresh period. Accordingly, each of the plurality of pixels P may display an image corresponding to the new data voltage Vdata in the hold period.

Each of the plurality of pixels P may provide a drive current corresponding to the data voltage Vdata to the light-emitting element EL to display an image during the hold period and maintain the turn-on state of the light-emitting element EL.

First, the driving of the pixel circuit and the light-emitting element during the refresh period in FIG. 5A will be described. Operation is possible in at least one bias interval Tobs1, Tobs2, an initialization interval Ti, a sampling interval Ts, and a light emission interval Te during the refresh period, but this is merely one embodiment and this order is not necessarily binding.

FIG. 5A shows that the pixel circuit may operate in at least one bias interval Tobs1, Tobs2 during the refresh period.

At least one bias interval Tobs1, Tobs2 is an interval where an on-bias stress operation OBS in which the bias voltage Vobs is applied is performed. High voltage is input at the light emission control signal EM(n), and the third and fourth transistors T3, T4 are turned off. Low voltage is input at the first scan signal SC1(n) and the fourth scan signal SC4(n), and the first transistor T1 and the seventh transistor T7 are turned off. High voltage is input at the second scan signal SC2, and the second transistor T2 is turned off.

Low voltage is input at the third scan signal SC3(n), and the fifth and sixth transistors T5, T6 are turned on. As the fifth transistor T5 is turned on, the bias voltage Vobs is applied to the first electrode of the drive transistor DT connected to the second node N2.

Here, the bias voltage Vobs is supplied to the third node N3, which is the drain electrode of the drive transistor DT, so that the charging time or charging delay of the voltage at the fifth node N5, which is the anode electrode of the light-emitting component EL, may be reduced during the light emission period. The drive transistor DT maintains a strong saturation state.

For example, as the bias voltage Vobs increases, the voltage of the third node N3, which is the drain electrode of the drive transistor DT, may increase, and the gate-source voltage or drain-source voltage of the drive transistor DT may decrease. Accordingly, the bias voltage Vobs is preferably greater than the data voltage Vdata at least.

At this time, the magnitude of the drain-source current Id passing through the drive transistor DT may decrease, and the stress of the drive transistor DT is reduced in a positive bias stress situation so that the charging delay of voltage at the third node N3 may be reduced or eliminated. In other words, performing the on-bias stress operation OBS before sampling the threshold voltage Vth of the drive transistor DT may alleviate the hysteresis of the drive transistor DT.

Accordingly, the on-bias stress operation OBS in at least one bias interval Tobs1, Tobs2 may be defined as an operation of directly applying a suitable bias voltage to the drive transistor DT during non-light-emitting periods.

In addition, as the sixth transistor T6 is turned on, the anode electrode (or pixel electrode) of the light-emitting element EL connected to the fifth node N5 is reset to the first initialization voltage VAR in at least one bias interval Tobs1, Tobs2.

However, the gate electrodes of the fifth and sixth transistors T5, T6 may be configured to receive separate scan signals and be independently controlled. Accordingly, it is not required to apply bias voltage simultaneously to the first electrode of the drive transistor DT and the anode electrode of the light-emitting device EL in the bias interval.

FIG. 5A shows that the pixel circuit may operate in the initialization interval Ti during the refresh period. The initialization interval Ti is an interval for initializing the gate electrode voltage of the drive transistor DT.

High voltage is input at the first scan signal SC1(n) to fourth scan signals SC4(n) and the light emission control signal EM(n), and the first transistor T1 and the seventh transistor T7 are turned on while the second to sixth transistors T2, T3, T4, T5, T6 are turned off. As the first and seven transistors T1, T7 are turned on, the gate electrode and the second electrode of the drive transistor DT connected to the first node N1 are reset to the second initial voltage Vini.

FIG. 5A shows that the pixel circuit may operate in the sampling interval Ts during the refresh period. The sampling interval is the period for sampling the threshold voltage Vth of the drive transistor DT.

A high voltage is input at the first scan signal SC1(n), third scan signal SC3(n), and the light emission control signal EM(n) while a low voltage is input at the second scan signal SC2(n) and the fourth scan signal SC4(n). Accordingly, the third to seventh transistors T3, T4, T5, T6, T7 are turned off, the first transistor T1 remains turned on, and the second transistor T2 is turned on. That is, the second transistor T2 is turned on so that the data voltage Vdata is applied to the drive transistor DT, while the first transistor T1 diode-connects the drive transistor DT between the first node N1 and the third node N3 so that the threshold voltage Vth of the drive transistor DT may be sampled.

FIG. 5A shows that the pixel circuit may operate in the light emission interval Te during the refresh period. The light emission interval Te is an interval for offsetting the sampled threshold voltage Vth and driving the light-emitting element EL with the drive current corresponding to the sampled data voltage.

A low voltage is input at the light emission control signal EM(n), and the third and fourth transistors T3, T4 are turned on.

As the third transistor T3 is turned on, the high potential drive voltage EVDD connected to the fourth node N4 is applied to the first electrode of the drive transistor DT connected to the second node N2 through the third transistor T3. The drive current Id supplied from the drive transistor DT to the light-emitting element EL through the fourth transistor T4 becomes independent of the value of the threshold voltage Vth of the drive transistor DT so that the threshold voltage Vth of the drive transistor DT is compensated for operation.

Next, the driving of the pixel circuit and light-emitting element during the hold period will be described with reference to FIG. 5B.

The hold period may include at least one bias interval Tobs3, Tobs4 and a light emission interval Te′. The description of the operation of the pixel circuit, which is the same as the operation during the refresh period, will be omitted.

As described above, a difference is that new data voltage Vdata is charged and is applied to the gate electrode of the drive transistor DT during the refresh period while the data voltage Vdata of the refresh period is maintained and used during the hold period. Accordingly, unlike during the refresh period, the initialization interval Ti and the sampling interval Ts are not required in the hold period.

One on-bias stress operation OBS may be sufficient in the operation during the hold period. However, in the present embodiment, the third scan signal SC3(n) during the hold period is driven in the same manner as the third scan signal SC3(n) during the refresh period for the convenience of the drive circuit, and consequently, the on-bias stress operation OBS is operated twice as during the refresh period.

The difference between the drive signal during the refresh period described with reference to FIG. 5A and the drive signal during the hold period in FIG. 5B lies in the second and fourth scan signals SC2(n), SC4(n). Since the initialization interval Ti and the sampling interval Ts are not required in the hold period, unlike the case of the refresh period, a high voltage is always input at the second scan signal SC2(n), and a low voltage is always input at the fourth scan signal SC4 (n). That is, the second and seventh transistors T2, T7 are turned off all the time.

FIG. 5C illustrates driving of the pixel circuit and a light-emitting element that does not perform an on-bias stress operation OBS in the hold period of FIG. 5B.

Referring to FIG. 5C, the pixel circuit may operate including only the emission interval Te″ during the hold period. In other words, in the pixel circuit, the on-bias stress operation OBS is not performed during the hold period, the second scan signal SC2(n) and the third scan signal SC3(n) are always high voltage, and the fourth scan signal SC4(n) is always at a low voltage. That is, the second transistor T2 and the fifth to seventh transistors T5, T6, and T7 are always turned off.

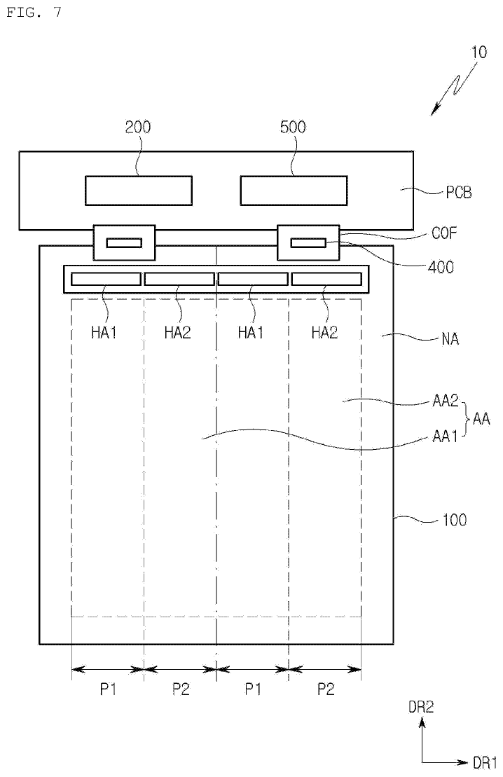

FIG. 6 is a plan layout of a display device according to an exemplary embodiment.

FIG. 6 shows that the display device 10 according to an embodiment may include the display area AA and non-display area NA adjacent to or at least partially surrounding the display area AA. As an example, the non-display area NA completely surrounds the display area AA on a plane but is not limited thereto.

A chip-on film COF may be attached to at least one end of the non-display area NA (e.g., one end in the second direction DR2). As an example, a plurality of chip-on films COF may be provided. The plurality of chip-on films COF may be spaced apart from each other in the first direction DR1. FIG. 6 illustrates only two chip-on films COF, but there may be three or more films or just one film. One or more printed circuit board PCB may be connected to the other end of the chip-on film COF. The controller 200 and the power supply portion 500 may be disposed on the PCB, without being limited thereto.

The non-display area NA may include a horizontal line area HA. The horizontal line area HA may be disposed between the display area AA and the chip-on film COF and extend in the first direction DR1. Gate control lines GCL connected to each of the first stage circuit portion 150a and the second stage circuit portion 150b may be disposed in the horizontal line area HA. As an example, the gate control lines GCL extending in the first direction DR1 in the horizontal line area HA may branch off in the second direction DR2 to be connected to each of the first stage circuit portion 150a and the second stage circuit portion 150b.

On the other hand, for the convenience of description in the present specification, the areas of the display area AA corresponding to each chip-on film COF may be separated out. For example, the display area AA may include a first display area AA1 corresponding to the chip-on film COF (hereinafter, first chip-on film) on the other side in the first direction DR1 and a second display area AA2 corresponding to the chip-on film COF (hereinafter, second chip-on film) on one side in the first direction DR1. The first display area AA1 may correspond to the first chip-on film COF in the second direction DR2 and the second display area AA2 may correspond to the second chip-on film COF in the second direction DR2, without being limited thereto.

FIG. 7 is a detailed view of the plan layout of a display device according to FIG. 6 according to an exemplary embodiment.

FIG. 7 shows that the horizontal line area HA may include a first horizontal line area HA1 and a second horizontal line area HA2. In addition, each display area AA1, AA2 may include a first stage area P1 for disposing the first stage circuit portion 150a and a second stage area P2 for disposing the second stage circuit portion 150b. That is, the first display area AA1 may include the first stage area P1 for disposing the first stage circuit portion 150a and the second stage area P2 for disposing the second stage circuit portion 150b, and the second display area AA2 may include the first stage area P1 for disposing the first stage circuit portion 150a and the second stage area P2 for disposing the second stage circuit portion 150b.

A plurality of first horizontal line areas HA1 and second horizontal line areas HA2 may be provided. For example, two first horizontal line areas HA1 and two second horizontal line areas HA2 may be provided respectively. The first and second horizontal line areas HA1, HA2 may be disposed in the horizontal line area HA corresponding to the first display area AA1 in the second direction DR2, and the first and second horizontal line area HA1, HA2 may be disposed in the horizontal line area HA corresponding to the second display area AA2 in the second direction DR2. In the second direction DR2, the first stage area P1 of the first display area AA1 may correspond to the first horizontal line area HA1, the second stage area P2 of the first display area AA1 may correspond to the second horizontal line area HA2, the first stage area P1 of the second display area AA2 may correspond to the first horizontal line area HA1, and the second stage area P2 of the second display area AA2 may correspond to the second horizontal line area HA2.

Therefore, a first horizontal line area HA1 and a second horizontal area HA2 may be disposed in the non-display area spaced apart from one another across direction DR1.

The second horizontal line area HA2 may be disposed between the adjacent first horizontal line areas HA1 and the first horizontal line areas HA1 may be disposed between the adjacent second horizontal line area HA2 in the horizontal line area HA. That is, the first horizontal line area HA1 and the second horizontal line area HA2 may be alternately disposed.

Further, the second stage area P2 may be disposed between the adjacent first stage areas P1 and the first stage area P1 may be disposed between the adjacent second stage areas P2 in the display area AA. That is, the first stage areas P1 and the second stage area P2 may be alternately disposed.

In one embodiment, one or more first power lines may be disposed across the horizontal line areas, where the one or more first power lines may be electrically connected to at least one pixel or pixels to supply one or more power voltages to the at least one pixel. Moreover, one or more second power lines connected to the one or more first power lines may be disposed, where the one or more second power lines intersect the horizontal lines.

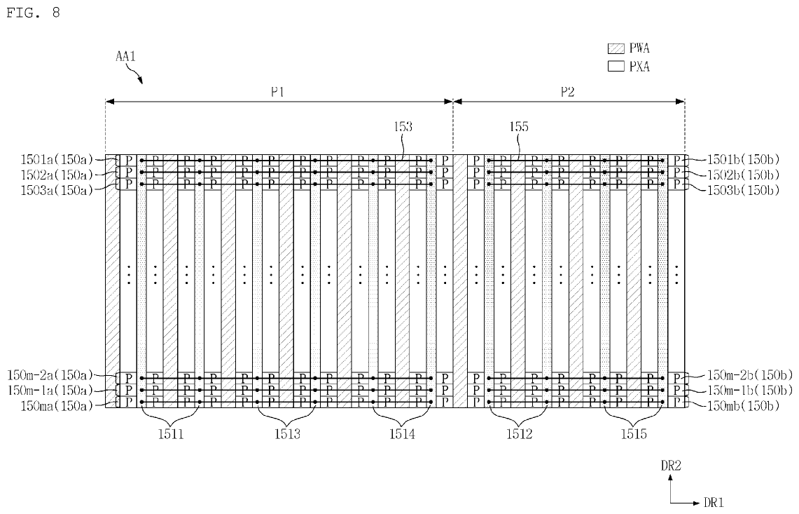

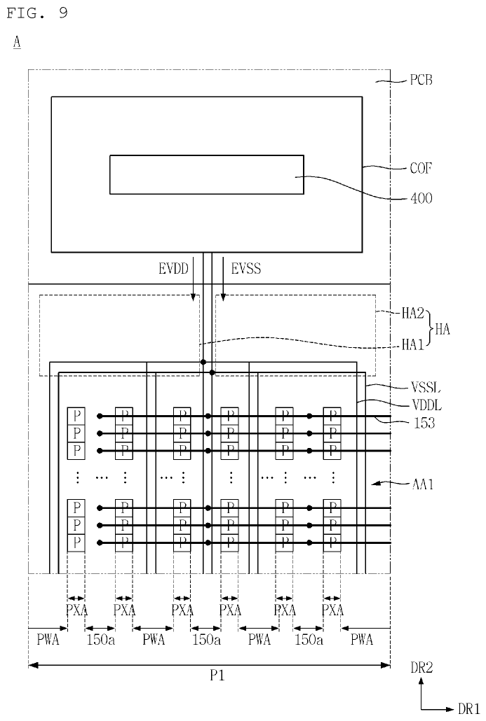

FIG. 8 is a detailed plan layout of a first display area according to FIG. 7 according to an exemplary embodiment.

FIG. 8 shows that the first stage circuit portion 150a may include a plurality of stage circuit portions 1501a to 150ma, and each of the plurality of stage circuit portions 1501a to 150ma may include a plurality of branch circuits 1511, 1513, 1514 and a first branch network 153, without being limited thereto. As an example, each of the plurality of stage circuit portions 1501a to 150ma may include more or less branch circuits.

Each of the plurality of branch circuits 1511, 1513, 1514 may be selectively connected to the gate control lines GCL in the first stage area P1 through the first branch network 153 and may be electrically connected to each other through the first branch network 153. Each of the plurality of branch circuits 1511, 1513, 1514 may generate scan signals or light emission control signals according to the gate control signals supplied through the gate control lines GCL and the voltage of the first branch network 153 and supply the generated scan signal or light emission control signal to the corresponding scan line SCL or light emission control signal line EML.

As an example, the plurality of branch circuits 1511, 1513, 1514 may include the first branch circuit 1511 connecting to the first scan line, the third branch circuit 1513 connecting to the third scan line, and the fourth branch circuit 1514 connecting to the fourth scan line connected to the pixel P.

Each of the plurality of branch circuits 1511, 1513, 1514 may include one TFT (or branch TFT) among the plurality of TFTs constituting one of the stage circuit portions 1501a through 150ma.

As illustrated in FIG. 8, each of the plurality of branch circuits 1511, 1513, 1514 may include sub-branch circuits spaced apart from each other in the first direction DR1. Each of the plurality of branch circuits 1511, 1513, 1514 includes two sub-branch circuits in FIG. 8 but is not limited thereto, and there may be one branch circuit or three or more branch circuits. Hereinafter, the description will focus on the plurality of branch circuits 1511, 1513, 1514 respectively including two sub-branch circuits.

Any one of the sub-branch circuits of each of the plurality of branch circuits 1511, 1513, 1514 may include a pull-up TFT connected to each scan line SCL. The other one of the sub-branch circuits of each of the plurality of branch circuits 1511, 1513, 1514 may include a pull-down TFT connected to the scan line SCL.

The first branch network 153 may be disposed on each horizontal line of the substrate 111 and electrically connect the plurality of branch circuits 1511, 1513, 1514 to each other. The first branch network 153 according to the embodiment may include a plurality of control node lines and a plurality of network lines.

The plurality of control node lines may be disposed on each horizontal line of the substrate 111 and be selectively connected to the plurality of branch circuits 1511, 1513, 1514 on one horizontal line.

The plurality of network lines may be selectively connected to the gate control lines GCL disposed on the substrate 111 and may be selectively connected to the plurality of branch circuits 1511, 1513, and 1514.

The second stage circuit portion 150b may include a plurality of stage circuit portions 1501b to 150mb, and the plurality of stage circuit portions 1501b to 150mb may respectively include a plurality of branch circuits 1512, 1515 and the first and second branch network 155, without being limited thereto. As an example, the plurality of stage circuit portions 1501b to 150mb may respectively include more or less branch circuits.

Each of the plurality of branch circuits 1512, 1515 is selectively connected to the gate control lines GCL in the second stage area P2 through the second branch network 155, and may be electrically connected to each other through the second branch network 155. Each of the plurality of branch circuits 1512, 1515 may generate a scan signal or a light emission control signal according to the gate control signals including, for example, one or more scan control signals and one or more emission control signals supplied through the gate control lines GCL and the voltage of the second branch network 155 and supply the generated scan signal or light emission control signal to the corresponding to the scan line SCL or the light emission control signal line EML.

The plurality of branch circuits 1512, 1515 may include the second branch circuit 1512 connecting to the second scan line and the fifth branch circuit 1515 connecting to the light emission control signal line connected to the pixel P.

Each of the plurality of branch circuits 1512, 1515 may include at least one TFT (or branch TFT) among the plurality of TFTs constituting one stage circuit portion 1501b to 150mb.

As illustrated in FIG. 8, each of the plurality of branch circuits 1512, 1515 may include sub-branch circuits spaced apart from each other in the first direction DR1. Each of the plurality of branch circuits 1512, 1515 includes two sub-branch circuits in FIG. 8 but is not limited thereto. There may be one sub-branch circuit or three or more sub-branch circuits. Hereinafter, the description will focus on each of the plurality of branch circuits 1512, 1515 respectively including two sub-branch circuits.

Any one of the sub-branch circuits of each of the plurality of branch circuits 1512, 1515 may include a pull-up TFT connected to each scan line SCL. The other one of the sub-branch circuits of each of the plurality of branch circuits 1512, 1515 may include a pull-down TFT connected to scan line SCL.

The second branch network 155 may be disposed in each horizontal line of the substrate 111 and the plurality of branch circuits 1512, 1515 may be electrically connected to each other. The second branch network 155 according to the embodiment may include a plurality of control node lines and a plurality of network lines.

The plurality of control node lines may be disposed on each horizontal line of the substrate 111 and may be selectively connected to the plurality of branch circuits 1512, 1515 on one horizontal line.

The plurality of network lines may be selectively connected to the gate control lines GCL disposed on the substrate 111 and may be selectively connected to the plurality of branch circuits 1512, 1515.

On the other hand, as illustrated in FIG. 8, the first display area AA1 may include a drive voltage line area PWA and a pixel area PXA. The second display area AA2 includes substantially the same components as the first display area AA1, and thus a detailed description thereof will be omitted.

A first drive voltage line supplying each pixel P with the high potential drive voltage EVDD supplied from the power source unit 500 and a second drive voltage line supplying each pixel P with the low potential drive voltage EVSS supplied from the power source unit 500 may be disposed in the drive voltage line area PWA. A plurality of pixels P may be disposed in the pixel area PXA. The plurality of pixels P may be disposed in a column in the second direction DR2 and pixels P forming one column may be disposed in one pixel area PXA but are not limited thereto. As an example, the plurality of pixels P may be disposed in a zigzag arrangement or randomly in the pixel area PXA, and the pixels P forming one of a plurality of columns may be disposed in one pixel area PXA.

As illustrated in FIG. 8, the drive voltage line area PWA, the pixel area PXA, and each of the sub-branch circuits of the branch circuits 1511, 1513, 1514 may be alternately disposed in the first direction DR1 in the first stage area P1. For example, the drive voltage line area PWA may be disposed between adjacent pixel areas PXA, and each of the sub-branch circuits of the branch circuits 1511, 1513, 1514 may be disposed between adjacent pixel areas PXA. The disposition of the drive voltage line area PWA, the pixel area PXA, and sub-branch circuits of the branch circuits 1511, 1513, 1514 in the first stage area P1 as illustrated in FIG. 8 is not limited thereto and may be variously modified. The drive voltage line area PWA, the pixel area PXA, and sub-branch circuits of the branch circuits 1512, 1515 may be alternately disposed in the first direction DR1 in the second stage area P2. For example, the drive voltage line area PWA may be disposed between adjacent pixel areas PXA, and each of the sub-branch circuits of the branch circuits 1512, 1515 may be disposed between adjacent pixel areas PXA. The disposition of the drive voltage line area PWA, the pixel area PXA, and sub-branch circuits of the branch circuits 1512, 1515, in the second stage area P2 illustrated in FIG. 8 is not limited thereto and may be variously modified.

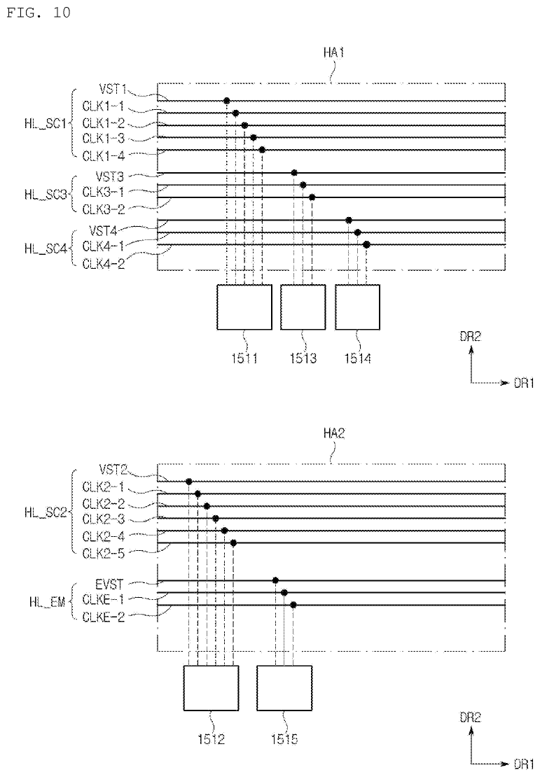

FIG. 9 is an enlarged plan view of area A in FIG. 6 according to an exemplary embodiment of the present disclosure.

As described above, one or more first power lines may be disposed across the horizontal line areas, where the one or more first power lines may be electrically connected to at least one pixel or pixels to supply one or more power voltages to the at least one pixel. FIG. 9 shows that the one or more first power lines may include a first drive voltage line VDDL and a second drive voltage VSSL may be disposed in the drive voltage line area PWA. The first drive voltage line VDDL and the second drive voltage line VSSL may respectively supply the high potential drive voltage EVDD and the low potential drive voltage EVSS to each pixel P from the power supply unit 500. The first drive voltage line VDDL and the second drive voltage line VSSL may respectively extend from the power supply unit 500 and may respectively extend in the first direction DR1 in the horizontal line area HA. Moreover, one or more second power lines connected to the one or more first power lines may be disposed, where the one or more second power lines intersect the horizontal lines in the horizontal areas. In one embodiment, when the data driver 400 is implemented as one or more chip-on-films (COF's), the one or more second power lines are disposed on the film of the COF adjacent to the integrated circuit. In another embodiment, at least a portion of the one or more second power lines extends through the data driver 400.

In one embodiment, the display panel 100 further includes a set of second gate control lines that are connected to the horizontal lines to supply the gate control signals to the horizontal lines, such that they are supplied to the pixels via the gate control lines GCL. In such an embodiment, the plurality of data lines DL may extend from a center of the integrated circuit to the display panel 100 (e.g., in a second direction), and the set of second gate control lines extends from an edge portion of the integrated circuit on the COF.

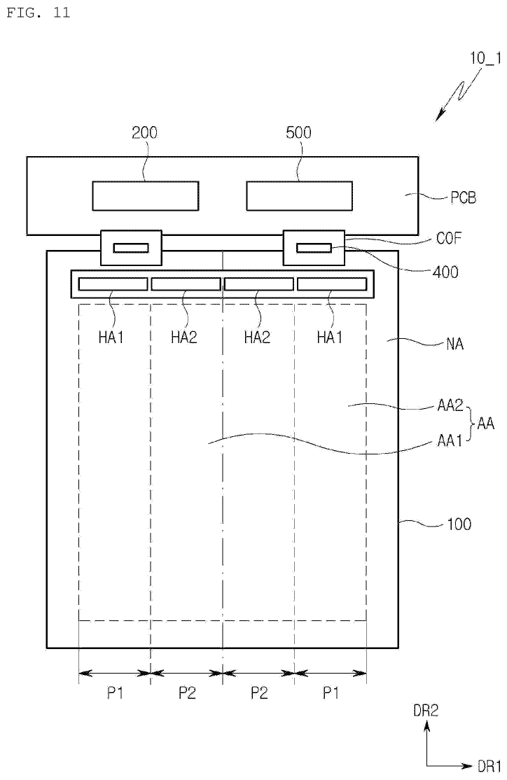

As described below in FIG. 10, the horizontal line area HA between the chip-on film COF and the display area AA may be divided into horizontal line areas HA1, HA2 spaced apart (or separated) from each other in the first direction DR1, and each of the horizontal lines HL_SC1, HL_SC2, HL_SC3, HL_SC4, HL_EM is disposed in each of the horizontal line areas HA1, HA2 according to the number of shift clock lines included in each of the horizontal lines HL_SC1, HL_SC2, HL_SC3, HL_SC4, HL_EM, and the horizontal lines HL_SC1, HL_SC2, HL_SC3, HL_SC4, HL_EM disposed in different horizontal line areas HA1, HA2 may be separated from each other in the first direction DR1. In contrast, the first drive voltage line VDDL and the second drive voltage line VSSL disposed in the horizontal line area HA may respectively extend in the first direction DR1 without distinction between the horizontal line areas HA1, HA2. The first drive voltage line VDDL and the second drive voltage line VSSL disposed in the horizontal line area HA may respectively branch off and be connected to each pixel (P). The connection between the first drive voltage line VDDL, the second drive voltage line VSSL, and the pixel P is widely known in the art and thus detailed description thereof is omitted.

In one embodiment at least one of the plurality of data lines DL, one or more first power lines, and the horizontal lines disposed in the horizontal line areas HA1, HA2 are disposed on a different layer than another one of the plurality of data lines DL, one or more first power lines, and the horizontal lines. In a further embodiment, a material of the horizontal lines in the horizontal line areas HA1, HA2 is different from a material of the plurality of data lines DL and/or a material of the one or more first power lines.

In a further embodiment the horizontal lines are formed in a same layer as the second gate electrode GE2 or the second source electrode SD3 or the second drain electrode SD4. In one embodiment, the one or more first power lines or the one or more second power lines may be formed in a same layer as the second source electrode SD3 or the second drain electrode SD4. In one embodiment, at least a portion of the one or more first power lines or the one or more second power lines is formed in a same layer as the intermediate electrode.

FIG. 10 is a view illustrating a first horizontal line area and a second horizontal line area according to an exemplary embodiment.

FIG. 10 shows that the gate control lines (refer to GCL in FIG. 3) may be disposed in the first horizontal line area HA1 and the second horizontal line area HA2 respectively. As described in detail in FIG. 3, the gate control line (refer to GCL in FIG. 3) may include a start signal line and a plurality of shift clock lines.

For example, a first horizontal line HL_SC1 connected to the first branch circuit 1511, a third horizontal line HL_SC3 connected to the third branch circuit 1513, and a fourth horizontal line HL_SC4 connected to the fourth branch circuit 1514 may be disposed in the first horizontal line area HA1, while a second horizontal line HL_SC2 connected to the second branch circuit 1512 and a fifth horizontal line HL_EM connected to the fifth branch circuit 1515 may be disposed in the second horizontal line area HA2. The first horizontal line HL_SC1 connected to the first branch circuit 1511, the third horizontal line HL_SC3 connected to the third branch circuit 1513, and the fourth horizontal line HL_SC4 connected to the fourth branch circuit 1514 may be arranged in the second direction DR2, without being limited thereto, and the second horizontal line HL_SC2 connected to the second branch circuit 1512 and a fifth horizontal line HL_EM connected to the fifth branch circuit 1515 may be arranged in the second direction DR2, without being limited thereto. In one embodiment, a branch circuit may be arranged along two or more columns in the display area.

For example, the first horizontal line HL_SC1 may include one first start signal line VST1 and four shift clock lines CLK1-1 to CLK1-4, the third horizontal line HL_SC3 may include one third start signal line VST3, two shift clock lines CLK3-1, CLK3-2, and the fourth horizontal line HL_SC4 may include one fourth start signal line VST4, two shift clock lines CLK4-1, CLK4-2. Thus, the first horizontal line HL_SC1 may include a set of first lines, electrically connected to at least the first stage circuit portion 150a (e.g., first branch circuit 1511). The third horizontal line HL_SC3 may include a set of third lines, electrically connected to the first stage circuit portion (e.g., third branch circuit 1513). The fourth horizontal line HL_SC4 may include a set of fourth lines, electrically connected to the first stage circuit portion (e.g., fourth branch circuit 1514). The second horizontal line HL_SC2 may include one second start signal line VST2 and five shift clock lines CLK2-1 to CLK2-5, and the fifth horizontal line HL_EM may include one fifth start signal line EVST and two shift clock lines CLKE-1, CLKE-2, without being limited thereto. As an example, each horizontal line may include more or less shift clock lines. Thus, the second horizontal line HL_SC2 may include a set of second lines, electrically connected to at least the second stage circuit portion 150b (e.g., second branch circuit 1512). The fifth horizontal line HL_EM may include a set of fifth lines, electrically connected to the second stage circuit portion (e.g., fifth branch circuit 1515).

That is, the horizontal lines HL_SC1, HL_SC3, HL_SC4 are disposed in the first horizontal line area HA1, and the horizontal lines HL_SC2, HL_EM are disposed in the second horizontal line area HA2, which may be designed according to the number of shift clock lines included in each horizontal line. Embodiments are not limited thereto. Each of the horizontal lines HL_SC1, HL_SC2, HL_SC3, HL_SC4 and HL_EM may be disposed in either of the first horizontal line area HA1 and the second horizontal line area HA2. As an example, each of the horizontal lines HL_SC1, HL_SC2, HL_SC3, HL_SC4 and HL_EM may be disposed in either of the first horizontal line area HA1 and the second horizontal line area HA2, such that the shift clock lines are evenly distributed in the first horizontal line area HA1 and the second horizontal line area HA2. As an example, the number of shift clock lines included in the first horizontal line area HA1 and the number of shift clock lines included in the second horizontal line area HA2 may be the same or similar. As an example, the difference between the number of shift clock lines included in the first horizontal line area HA1 and the number of shift clock lines included in the second horizontal line areas HA2 may be less than 5, less than 3, less than 2 or even 0, without being limited thereto.

In the embodiment, since the second horizontal line HL_SC2 has the largest number of shift clock lines CLK2-1 to CLK2-5, followed by the first horizontal line HL_SC1 having the second largest number of shift clock lines CLK1-1 to CLK1-4, the second horizontal line HL-SC2 and the first horizontal line HL_SC1 may be separately disposed in the first horizontal line area HA1 and the second horizontal line area HA2 respectively. Further, since the second horizontal line HL_SC2 has the number of shift clock lines CLK2-1 to CLK2-5, two horizontal lines among the remaining three horizontal lines HL_SC3, HL_SC4, HL_EM may be disposed in the same horizontal line area HA1, HA2 as the first horizontal line HL_SC1, and the remaining one horizontal line may be disposed in the same horizontal line area HA1, HA2 as the second horizontal line HL_SC2, without being limited thereto.

According to the embodiment, the horizontal line area HA between the chip-on film COF and the display area AA is divided into horizontal line areas HA1, HA2 spaced apart (or separated) from each other, and the horizontal line HL_SC1, HL_SC2, HL_SC3, HL_SC4, HL_EM may be respectively disposed in each of the horizontal line areas HA1, HA2 according to the number of shift clock lines included in each of horizontal line HL_SC1, HL_SC2, HL_SC3, HL_SC4, HL_EM. As a result, the horizontal line areas HA1, HA2 may be designed to have a similar width in the second direction DR2 so that there is an advantage in that the bezel area occupied by the horizontal line area HA may be significantly reduced. As another example, the widths in the second direction DR2 of the first horizontal line area HA1 and the second horizontal line area HA2 could be different from each other depending on the number of shift clock lines included therein, without being limited thereto.

In some embodiments, the third horizontal line HL_SC3 or the fourth horizontal line HL_SC4 having the same shift clock lines, instead of the fifth horizontal line HL_EM, may be disposed in the second horizontal line area HA2. In this case, the fifth horizontal line HL_EM may be disposed in the first horizontal line area HA1.

Display devices according to other embodiments will be described below.

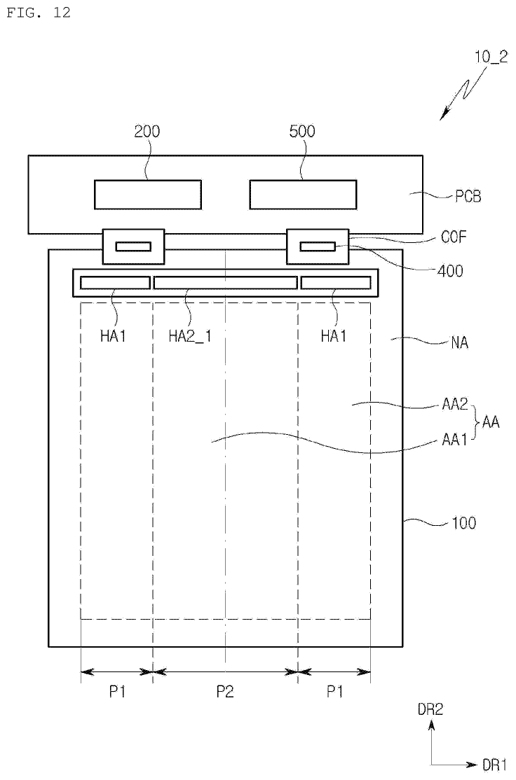

FIG. 11 is a plan layout of a display device according to another embodiment.

FIG. 11 shows that a display device 10_1 according to the present embodiment differs from the display device 10 illustrated in FIG. 7 in that the second horizontal line area HA2 corresponding to the second display area AA2 of the display device 101 (hereinafter, corresponding in the second direction DR2) is disposed between the first horizontal line area HA1 corresponding to the second display area AA2 and the second horizontal line area HA2 corresponding to the first display area AA1.

More specifically, the second horizontal line area HA2 corresponding to the second display area AA2 of the display device 10_1 according to the present embodiment may be disposed between the first horizontal line area HA1 corresponding to the second display area AA2 and the second horizontal line area HA2 corresponding to the first display area AA1. The second stage area P2 of the second display area AA2 may be disposed between the first stage area P1 of the second display area AA2 and the second stage area P2 of the first display area AA1.

In one embodiment, there is disposed a first horizontal area HA1 and a second horizontal area HA2 corresponding to the first display area AA1, and another first horizontal area HA1 and another second horizontal area HA2 corresponding to the second display area AA2. The another set of first lines, third lines, and fourth lines in the another first horizontal area HA1 may be electrically connected to another first stage circuit portion in the second display area AA2. Another set of second lines and fifth lines in the another second horizontal area HA2 may be electrically connected to another second stage circuit portion in the second display area AA2.

According to the present embodiment, the horizontal line area HA between the chip-on film COF and the display area AA is divided into horizontal line areas HA1, HA2 spaced apart (or separated) from each other, and the horizontal line (HL_SC1, HL_SC2, HL_SC3, HL_SC4, HL_EM may be respectively disposed in each of the horizontal line areas HA1, HA2 according to the number of shift clock lines included in each of the horizontal lines (HL_SC1, HL_SC2, HL_SC3, HL_SC4, and HL_EM). As a result, each of the horizontal line areas HA1, HA2 may be designed to have a similar width in the second direction DR2, so that there is an advantage in that the bezel area occupied by the horizontal line areas HA may be significantly reduced.

Other descriptions have been provided in FIGS. 7 to 10 above, and thus, a detailed description will be omitted below.

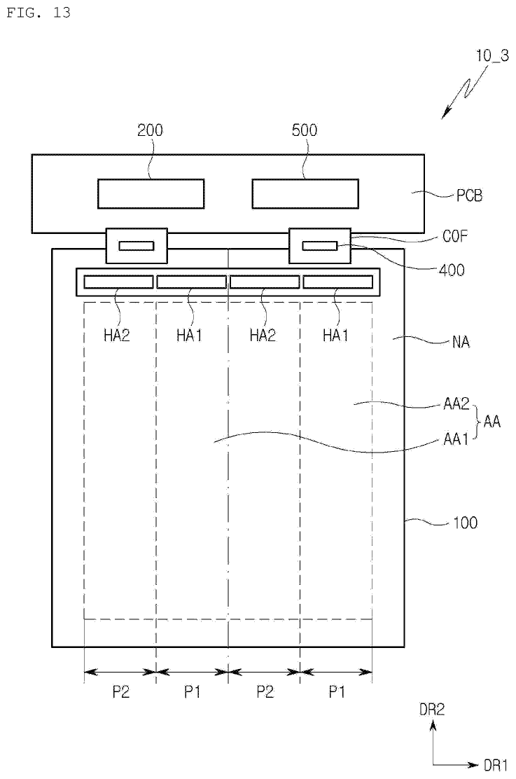

FIG. 12 is a plan layout of a display device according to still another exemplary embodiment.

FIG. 12 shows that a display device 10_2 according to the present embodiment differs from the display device 10-1 illustrated in FIG. 11 in that the second horizontal line area HA2_1 of the display device 10-2 is disposed between adjacent first horizontal line areas HA1 and is integrally formed.

More specifically, the second horizontal line area HA2_1 corresponding to the first display area AA1 (hereinafter, corresponding in the second direction DR2) and the second horizontal line area HA2_1 corresponding to the second display area AA2 may be integrally formed. That is, the second horizontal line HL_SC2 and the fifth horizontal line HL_EM described above in FIG. 10 may integrally extend respectively in the first direction DR1 in the horizontal line area HA2_1 of the horizontal line area corresponding to the first display area AA1 and the second display area AA2. In one embodiment, there is disposed a first horizontal area HA1 and a second horizontal area HA2_1 corresponding to the first display area AA1 and the second display area AA2, and another first horizontal area HA1 corresponding to the second display area AA2. The another set of first lines, third lines, and fourth lines in the another first horizontal area HA1 may be electrically connected to another first stage circuit portion in the second display area AA2.

The second stage area P2 of the first display area AA1 and the second stage area P2 of the second display area AA2 may also be integrally formed.

According to the present embodiment, the horizontal line area HA between the chip-on film COF and the display area AA is divided into the horizontal line areas HA1, HA2_1 spaced apart (or separated) from each other, and the horizontal lines HL_SC1, HL_SC2, HL_SC3, HL_SC4, HL_EM may be respectively disposed in each of the horizontal line areas HA1, HA2_1 according to the number of shift clock lines included in each of the horizontal lines HL_SC1, HL_SC2, HL_SC3, HL_SC4, HL_EM. As a result, the horizontal line areas HA1, HA2_1 may be designed to have a similar width in the second direction DR2 so that there is an advantage in that the bezel area occupied by the horizontal line area HA may be significantly reduced.

Other descriptions have been provided in FIGS. 7 to 11 above and thus detailed descriptions will be omitted.

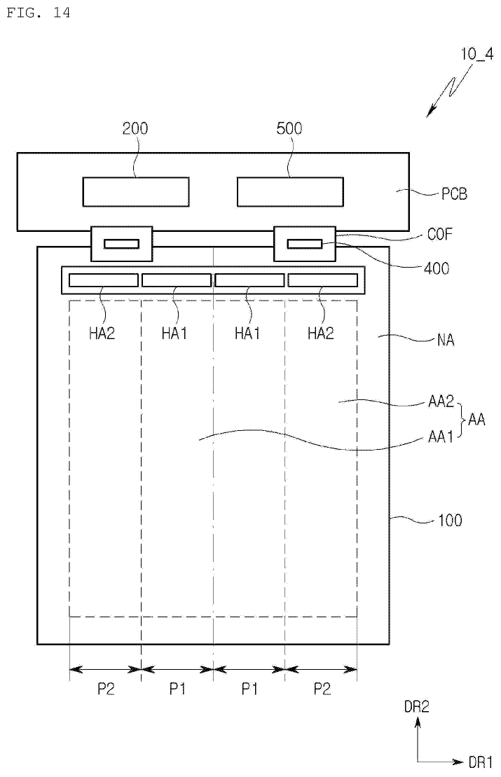

FIG. 13 is a plan layout of a display device according to still another embodiment.

FIG. 13 shows that a display device 10_3 according to the present embodiment differs from the display device 10 illustrated in FIG. 7 in that the second horizontal line area HA2 and the first horizontal line area HA1 corresponding to the first display area AA1 (hereinafter, corresponding in the second direction DR2) and the second horizontal line area HA2 and the first horizontal line area HA1 corresponding to the second display area AA2 are arranged in the direction from the other side of the first direction DR1 to one side of the first direction DR1.

Similarly, the second stage area P2 and the first stage area P1 of the first display area AA1 and the second stage area P2 and the first stage area P1 of the second display area AA2 may be arranged in the direction from the other side of the first direction DR1 to one side of the first direction DR1.

According to the present embodiment, the horizontal line area HA between the chip-on film COF and the display area AA may be divided into the horizontal line areas HA1, HA2, spaced apart (or separated) from each other, and the horizontal lines HL_SC1, HL_SC2, HL_SC3, HL_SC4, HL_EM may be respectively disposed in each of the horizontal line areas HA1, HA2 according to the number of shift clock lines included in each of the horizontal lines HL_SC1, HL_SC2, HL_SC3, HL_SC4, HL_EM. As a result, each of the horizontal line areas HA1, HA2 may be designed to have a similar width in the second direction DR2, so that the bezel area occupied by the horizontal line area HA may be significantly reduced.

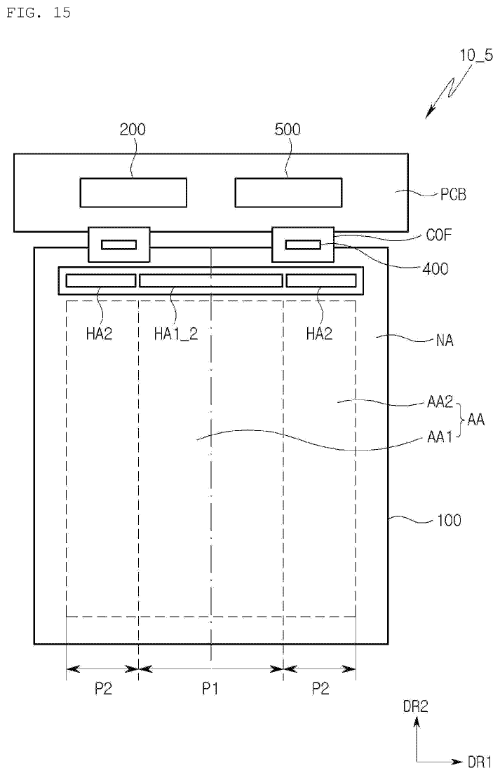

FIG. 14 is a plan layout of a display device according to still another exemplary embodiment.

FIG. 14 shows that a display device 10-4 according to the present embodiment differs from the display device 10_3 illustrated in FIG. 13 in that the first horizontal line area HA1 corresponding to the second display area AA2 of the display device 104 (hereinafter, corresponding in the second direction DR2) is disposed between the second horizontal line area HA2 corresponding to the second display area AA2 and the first horizontal line area HA1 corresponding to the first display area AA1.

The first stage area P1 of the second display area AA2 may be disposed between the second stage area P2 of the second display area AA2 and the first stage area P1 of the first display area AA1.

According to the present embodiment, the horizontal line area HA between the chip-on film COF and the display area AA is divided into horizontal line areas HA1, HA2 spaced apart (or separated) from each other, and the horizontal lines HL_SC1, HL_SC2, HL_SC3, HL_SC4, HL_EM may be respectively disposed in each of the horizontal line areas HA1, HA2 according to the number of shift clock lines included in each of the horizontal lines HL_SC1, HL_SC2, HL_SC3, HL_SC4, HL_EM. As a result, each of the horizontal line areas HA1, HA2 may be designed to have a similar width in the second direction DR2, so that the bezel area occupied by the horizontal line area HA may be significantly reduced.

FIG. 15 is a plan layout of a display device according to still another exemplary embodiment.

FIG. 15 shows that a display device 10_5 according to the present embodiment differs from the display device 10_4 illustrated in FIG. 14 in that the first horizontal line area HA1_2 of the display device 10_5 is disposed between adjacent second horizontal line areas HA2 and is integrally formed.

More specifically, the first horizontal line area HA1_2 corresponding to the first display area AA1 (hereinafter, corresponding in the second direction DR2) and the first horizontal line area HA1_2 corresponding to the second display area AA2 may be integrally formed. That is, the first, third, and fourth horizontal lines HL_SC1, HL_SC3, HL_SC4 described above in FIG. 10 may integrally extend in the first direction DR1 in the first horizontal line area HA1_2 of the horizontal line area corresponding to the first display area AA1 and the second display area AA2, respectively. In one embodiment, there is disposed a second horizontal area HA2 and a first horizontal area HA1_2 corresponding to the first display area AA1 and the second display area AA2, and another second horizontal area HA2 corresponding to the second display area AA2. The another set of second lines and fifth lines in the another second horizontal area HA2 may be electrically connected to another second stage circuit portion in the second display area AA2.

The first stage area P1 of the first display area AA1 and the first stage area P1 of the second display area AA2 may be integrally formed.

According to the present embodiment, the horizontal line area HA between the chip-on film COF and the display area AA is divided into horizontal line areas HA1_1, HA2 spaced apart (or separated) from each other, and the horizontal lines HL_SC1, HL_SC2, HL_SC3, HL_SC4, HL_EM may be respectively disposed in each of the horizontal line areas HA1_1, HA2 according to the number of shift clock lines included in each of the horizontal lines HL_SC1, HL_SC2, HL_SC3, HL_SC4, HL_EM. As a result, each of the horizontal line areas HA1_1, HA2 may be designed to have a similar width in the second direction DR2, so that the bezel area occupied by the horizontal line area HA may be significantly reduced.

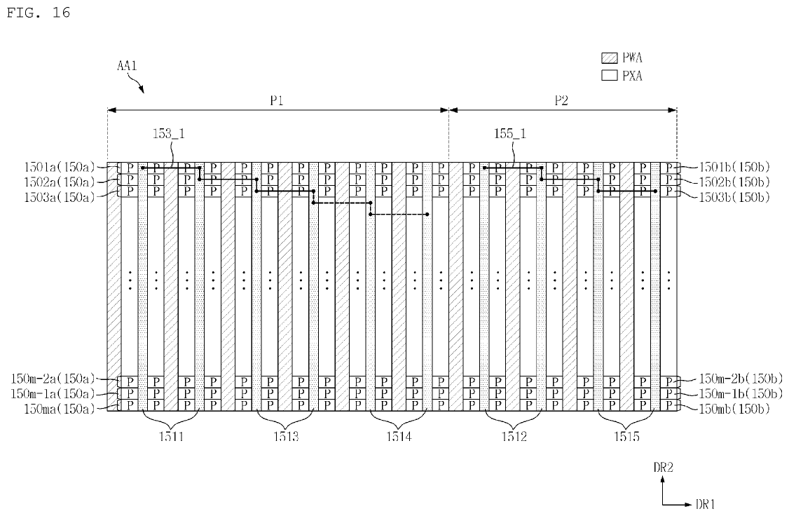

FIG. 16 is a detailed plan layout of a first display area according to another embodiment.

FIG. 16 shows that the embodiment differs from the embodiment in FIG. 8 in that each of a branch network 153_1 and a second branch network 155_1 extends downward (e.g. the second direction DR2) in a step shape.

More specifically, the first branch network 153_1 may extend in the first direction DR1 up to the sub-branch circuits of the first branch circuit 1511, bend downward to extend, and then extend again from the right sub-branch circuit of the first branch circuit 1511 to the left sub-branch circuit of the third branch circuit 1513. In this manner, the first branch network 153_1 may extend from the first branch circuit 1511 to the fourth branch circuit 1514. Similarly, the second branch network 155_1 may extend in the first direction DR1 up to the sub-branch circuits of the second branch circuit 1512, bend downward to extend, and then extend again from the right sub-branch circuit of the second branch circuit 1512 to the left sub-branch circuit of the fifth branch circuit 1515. In this manner, the second branch network 155_1 may extend from the second branch circuit 1512 to the fifth branch circuit 1515.

However, the step shape of the first and second branch networks 153_1, 1551 illustrated in FIG. 16 is not limited thereto.

According to some embodiments, a display device includes a display panel including a display area including pixels and a scan driver connected to the pixels and a non-display area disposed around the display area, and a first chip-on film attached to an end of the display panel, wherein the non-display area includes a horizontal line area disposed between the first chip-on film and the display area on a plane and the horizontal line area includes a first horizontal line area and a second horizontal line area spaced apart from each other in a first direction.

The display area may include a first stage area corresponding to the first horizontal line area in a second direction cross the first direction and a second stage area corresponding to the second horizontal line area in the second direction, wherein a first stage circuit portion may be disposed in the first stage area and a second stage circuit portion different from the first stage circuit portion may be disposed in the second stage area.

The first stage circuit portion may include a first branch circuit, a third branch circuit, and a fourth branch circuit, and the second stage circuit portion may include a second branch circuit and a fifth branch circuit.

The first branch circuit may output a first scan line connected to the pixel, the second branch circuit may output a second scan line connected to the pixel, the third branch circuit may output a third scan line connected to the pixel, the fourth branch circuit may output a fourth scan line connected to the pixel, and the fifth branch circuit may output a light emission control signal line connected to the pixel.

The first horizontal line area may include a first horizontal line connected to the first branch circuit, a third horizontal line connected to the third branch circuit, and a fourth horizontal line connected to the fourth branch circuit, and the second horizontal line area may include a second horizontal line connected to the second branch circuit and a fifth horizontal line connected to the fifth branch circuit.

The first to fifth horizontal lines may respectively include a plurality of shift clock lines, and the second horizontal line may include the largest number of the shift clock lines.

A second chip-on film spaced apart from the first chip-on film in the first direction may be further included.

The display area may include a first display area corresponding to the first chip-on film in the second direction and a second display area corresponding to the second chip-on film in the second direction, wherein two first horizontal line areas and two second horizontal line areas may be provided respectively.

The second horizontal line area corresponding to the first display area in the second direction may be disposed between the first horizontal line area corresponding to the first display area in the second direction and the first horizontal line area corresponding to the second display area in the second direction.

The second horizontal line area corresponding to the first display area in the second direction may be disposed between the first horizontal line area corresponding to the first display area in the second direction and the first second horizontal line area corresponding to the second display area in the second direction.

The second horizontal line area corresponding to the first display area in the second direction and the second horizontal line area corresponding to the second display area in the second direction may be integrally formed with each other, and the second horizontal line and the fifth horizontal line respectively disposed in the second horizontal line area corresponding to the first display area in the second direction and the second horizontal line area corresponding to the second display area in the second direction may integrally extend respectively.

The first horizontal line area corresponding to the first display area in the second direction may be disposed between the second horizontal line area corresponding to the first display area in the second direction and the second horizontal line area corresponding to the second display area in the second direction.

The first horizontal line area corresponding to the first display area in the second direction may be disposed between the second horizontal line area corresponding to the first display area in the second direction and the first horizontal line area corresponding to the second display area in the second direction.

The first horizontal line corresponding to the first display area in the second direction and the first horizontal line corresponding to the second display area in the second direction may be integrally formed with each other, and the first horizontal line, the third horizontal line, and the four horizontal lines respectively disposed in the first horizontal line area corresponding to the first display area in the second direction and the first horizontal line area corresponding to the second display area in the second direction may integrally extend respectively.

The foregoing description and accompanying drawings are merely illustrative representations of the technical ideas, and those skilled in the art to which the present specification pertains will be able to make various modification and variations, such as combinations, separations, substitutions, and changes, in the configuration within the scope not deviating from the essential characteristics. Therefore, the embodiments disclosed herein are intended to illustrate, rather than limit, the technical ideas, and the scope of the technical ideas are not limited by such embodiments. The scope of protection should be interpreted based on the claims below, and all technical ideas within the equivalent scope should be interpreted as included within the scope of the claims.

What is claimed is:

1. A display device comprising:
a display panel including a display area and a non-display area, the display area including at least one pixel;
a gate driver in the display area of the display panel, wherein the gate driver is configured to supply one or more gate signals to the at least one pixel;
a set horizontal lines disposed in a horizontal line area in the non-display area, wherein the set of horizontal lines are electrically connected to the gate driver to supply one or more gate control signals to the gate driver;
one or more first power lines disposed in the horizontal line area in the non-display area, wherein the one or more first power lines are electrically connected to the at least one pixel to supply one or more power voltages to the at least one pixel; and
one or more second power lines connected to the one or more first power lines, wherein the one or more second power lines intersect the set of horizontal lines.

2. The display device of claim 1, further comprising:
a set of data lines connected to the at least one pixel to supply one or more data signals to the at least one pixel,
wherein at least one of the set of data lines, one or more first power lines, and the set of horizontal lines are disposed on a different layer than another one of the set of data lines, one or more first power lines, and the set of horizontal lines.

3. The display device of claim 1, wherein the at least one pixel includes:
at least one first thin film transistor including a first active layer formed of polysilicon, a first source electrode, a first drain electrode, and a first gate electrode; and
at least one second thin film transistor including a second active layer formed of oxide semiconductor, a second source electrode, a second drain electrode, and a second gate electrode.

4. The display device of claim 3, further comprising a set of data lines connected to the at least one pixel, wherein a material of the set of horizontal lines is different from a material of the set of data lines and a material of the one or more first power lines.

5. The display device of claim 4, wherein the set of horizontal lines is formed in a same layer as the second gate electrode or the second source electrode or the second drain electrode.

6. The display device of claim 4, wherein the one or more first power lines or the one or more second power lines is formed in a same layer as the second source electrode or the second drain electrode.

7. The display device of claim 4, wherein the at least one pixel includes an intermediate electrode electrically connected to the first source electrode or the first drain electrode, and wherein at least a portion of the one or more first power lines or the one or more second power lines is formed in a same layer as the intermediate electrode.

8. The display device of claim 4, wherein the one or more data lines is formed in a same layer as the first gate electrode.

9. The display device of claim 4, wherein the at least one pixel further includes a storage capacitor including a first capacitor electrode and a second capacitor electrode, wherein the one or more data lines is formed in a same layer as the second capacitor electrode.

10. The display device of claim 1, further comprising:
a data driver connected to the display panel to supply the set of gate control signals to the set of horizontal lines, wherein the data driver is implemented as a chip-on-film (COF) including a film and the data driver is an integrated circuit on the film.

11. The display device of claim 10,
wherein at least a portion of the one or more second power lines is disposed on the film of the COF adjacent to the integrated circuit.

12. The display device of claim 10,
wherein at least a portion of the one or more second power lines extends through the data driver.

13. The display device of claim 10, further comprising:
a set of data lines connected to the at least one pixel;
a set of second gate control lines connected to the set of horizontal lines,
wherein the set of data lines extends from a center of the integrated circuit, and
wherein the set of second gate control lines extends from an edge portion of the integrated circuit.

14. The display device of claim 1, wherein the gate driver includes a branch circuit configured to generate a gate signal, and components of the branch circuit are arranged along two or more columns in the display area.

15. The display device of claim 1, wherein the gate driver includes at least a scan control driver and a light emission (EM) control signal driver, and wherein the scan control driver is configured to receive one or more scan control signals and the EM control signal driver is configured to receive one or more emission control signals.

16. The display device of claim 15, wherein a number of the one or more scan control signals is different from a number of the one or more emission control signals.

17. The display device of claim 15,
wherein the gate driver includes at least a second scan control driver configured to receive one or more second scan control signals,
wherein the scan control driver is configured to generate at least one scan signal and the second control scan driver is configured to generate at least one second scan signal, and
wherein a number of the one or more scan control signals is different from a number of the one or more second scan control signals.

18. The display device of claim 15,
wherein the gate driver includes at least a second scan control driver configured to receive one or more second scan control signals,
wherein the scan driver is configured to generate at least one scan signal and the second scan driver is configured to generate at least one second scan signal, and
wherein a signal of the one or more scan control signals is different from a signal of the one or more second scan control signals.

19. The display device of claim 1, wherein a first power line and a second power line is configured to supply a high potential drive voltage EVDD, and another first power line and another second power line is configured to supply a low potential drive voltage.

20. The display device of claim 1, further comprising a power supply unit configured to supply one or more drive voltages to the one or more first power lines and the one or more second power lines.
